(19) United States
(12) Patent Application Publication
(10) Pub. No.: US 2025/0093827 A1
(43) Pub. Date: Mar. 20, 2025

(54) EVALUATION DEVICE, EVALUATION METHOD, AND PROGRAM

(71) Applicant: Panasonic Intellectual Property Management Co., Ltd., Osaka (JP)

(72) Inventors: MIKIO USHIODA, Osaka (JP); NOBUO HARA, Osaka (JP)

(21) Appl. No.: 18/963,686

(22) Filed: Nov. 28, 2024

Related U.S. Application Data
(63) Continuation of application No. PCT/JP2023/018114, filed on May 15, 2023.

(30) Foreign Application Priority Data
Jun. 8, 2022 (JP) 2022-093250

(51) Int. Cl. G05B 13/02; G06N 7/01

(52) U.S. Cl. CPC G05B 13/0265; G06N 7/01

(57) ABSTRACT

Evaluation device (100) is a device that evaluates, by Bayesian optimization, unknown characteristic points corresponding to a plurality of candidate control points at a second time following a first time based on known characteristic points corresponding to controlled control points at the first time, the device including: reception controller (10) that acquires control result data (222) indicating the controlled control points at the first time and the known characteristic points at the first time, purpose data (212) indicating an optimization purpose, constraint condition data (213) indicating a constraint condition, and region reduction rule data (214); evaluation value calculating unit (12) that calculates an evaluation value of each of the plurality of unknown characteristic points based on control result data (222), purpose data (212), constraint condition data (213), and region reduction rule data (214); and evaluation value output unit (13) that outputs an evaluation value.

### TECHNICAL FIELD

The present disclosure relates to a technique for efficiently controlling product characteristic values within a standard in mass production of general industrial products.

### BACKGROUND ART

In mass production sites of industrial products, it is necessary to control set process conditions under optimal conditions so as to satisfy requirements of required product characteristics, such as standards for determining quality of industrial products. For example, at a mass production site (production process) of an electrode plate of a battery, a temperature, a viscosity and a flow rate of slurry, a pump rotation speed, room temperature, and the like are set as process conditions, and a coating weight and the like are set as product characteristics.

The optimal solution of a process condition can often be searched with a mathematical optimization approach if the relationship between the process condition and the product characteristic can be expressed by a physical formula. However, when the relationship is unknown, one set of combinations (that is, control points) of the values of the process conditions is selected, and actual control (that is, production) is performed. Then, as a control result, a combination (that is, a characteristic point) of values of product characteristics corresponding to the control point is obtained. By repeating such control, an optimal solution of the process condition can be searched for.

In general, in a mass production site affected by complicated manufacturing or various disturbances, in a case where a response to a change is delayed or accuracy of a response to a change is low, a large number of defective products are produced, and a production loss such as a large amount of money or time cost is consumed occurs. Therefore, in order to perform mass production operations with less production loss, it is important to search for an optimal solution (that is, optimal process conditions) quickly and with high accuracy.

Conventionally, in control of time-series data at a mass production site, an approach of intuition or experience by a site worker, and an approach using classical control or modern control theory have been used for searching for an optimal solution thereof. However, intuition or experience approaches depend on the ability of the site worker. In addition, the approach using the classical control or the modern control theory requires trial and error of an analyst at a stage such as parameter adjustment which is a search stage of an optimum solution. Note that, in the case of this approach, depending on parameter adjustment, an overshoot phenomenon in which a characteristic value exceeds a target value or a hunting phenomenon in which the characteristic value vibrates near the target value occurs. For example, Patent Literature 1 discloses a method for systematically executing adjustment of a gain value using PID control, which is one of modern control methods.

Furthermore, in recent years, in the field of machine learning, a data-driven approach using Bayesian optimization has attracted attention (see, for example, Non-Patent Document 1 and Non-Patent Document 2). The Bayesian optimization is an optimization method in which a Gaussian process is assumed as a mathematical model that represents a correspondence between input and output. In a case where the Bayesian optimization is used in a system in which a set of input/output relationships is obtained each time control is performed, every time a control result is obtained, a predicted distribution marginalized with a known control result is calculated on the basis of a simultaneous distribution of correspondence that can be calculated from the known control result. Further, an evaluation criterion called an acquisition function is used to select an optimum next control condition. As a result, it is possible to perform quantitative evaluation regardless of the ability of the analyst, and it is also possible to contribute to the automation of the optimal solution search work.

### CITATION LIST

### Patent Literature

PTL 1: Unexamined Japanese Patent Publication No. 2021-111017

### Non-Patent Literature

NPL 1: M. Emmerich, A. Deutz, J. W. Klinkenberg, “The computation of the expected improvement in dominated hypervolume of Pareto front approximations,” Repport Technique, Leiden University, Vol. 34, 2008.
NPL 2: M. Abdolshah, A. Shilton, S. Rana, S. Gupta, S. Venkatesh, “Expected Hypervolume Improvement with Constraints,” International Conference on Pattern Recognition (ICPR), 2018.

### SUMMARY OF THE INVENTION

An evaluation device according to an aspect of the present disclosure is an evaluation device that evaluates, by Bayesian optimization, a plurality of unknown characteristic points corresponding to a plurality of candidate control points at a second time following a first time based on a known characteristic point corresponding to a controlled control point at the first time, the evaluation device including: a first reception means that acquires control result data indicating the controlled control point at the first time and the known characteristic point at the first time; a second reception means that acquires purpose data indicating an optimization purpose, each of the plurality of unknown characteristic points indicating values of one or a plurality of product characteristics, and at least one product characteristic among the one or the plurality of product characteristics having the optimization purpose; a third reception means that acquires constraint condition data indicating a constraint condition applied to the at least one product characteristic; a fourth reception means that acquires region reduction rule data indicating a division method of a characteristic space represented by the at least one product characteristic and indicating a dimension for reducing an active region for each region of the characteristic space divided by the division method; a calculation means that calculates an evaluation value of each of the plurality of unknown characteristic points based on the control result data, the purpose data, the constraint condition data, and the region reduction rule data; and an output means that outputs the evaluation value, in which the calculation means applies weighting according to a degree of conformity of the constraint condition to the evaluation value for the at least one product characteristic.

### BRIEF DESCRIPTION OF THE DRAWINGS

FIG. 1 is a view for explaining a schematic operation of an evaluation device according to an exemplary embodiment.

FIG. 2 is a diagram illustrating an example in which each candidate control point and each characteristic point according to the exemplary embodiment are graphically represented.

FIG. 3A is a diagram illustrating a submatrix according to the exemplary embodiment.

FIG. 3B is a diagram illustrating a submatrix according to the exemplary embodiment.

FIG. 4 is a diagram illustrating a configuration of an evaluation device according to the exemplary embodiment.

FIG. 5 is a block diagram illustrating a functional configuration of an arithmetic circuit according to the exemplary embodiment.

FIG. 6 is a view illustrating an example of a reception image displayed on a display unit for receiving an input of setting information according to the exemplary embodiment.

FIG. 7 is a diagram illustrating an example of a reception image displayed on a display unit for receiving an input of region reduction rule data according to the exemplary embodiment.

FIG. 8 is a diagram illustrating an example of region reduction rule data according to the exemplary embodiment.

FIG. 9A is a view illustrating an example of a standard range according to the exemplary embodiment.

FIG. 9B is a view illustrating another example of the standard range according to the exemplary embodiment.

FIG. 10 is a flowchart illustrating a processing operation of the evaluation device according to the exemplary embodiment.

FIG. 11A is a diagram illustrating an example of candidate control point data according to the exemplary embodiment.

FIG. 11B is a diagram illustrating another example of the candidate control point data according to the exemplary embodiment.

FIG. 12 is a diagram illustrating an example of control result data according to the exemplary embodiment.

FIG. 13 is a diagram for explaining processing by an evaluation value calculating unit according to the exemplary embodiment.

FIG. 14 is a diagram illustrating an example of predicted distribution data according to the exemplary embodiment.

FIG. 15A is a view illustrating an example of an improvement region according to the exemplary embodiment.

FIG. 15B is a view illustrating another example of the improvement region according to the exemplary embodiment.

FIG. 16A is a diagram for explaining a method of calculating a volume of an improvement region according to the exemplary embodiment.

FIG. 16B is a view illustrating an example in which the whole characteristic space is divided into a plurality of small regions according to the exemplary embodiment.

FIG. 16C is a view illustrating an example of a lower end point and an upper end point of the small region according to the exemplary embodiment.

FIG. 17 is a diagram illustrating an example of a characteristic space divided into regions in a case where the region reduction rule according to the exemplary embodiment is applied.

FIG. 18A is a diagram illustrating another example of a characteristic space divided into regions in a case where the region reduction rule according to the exemplary embodiment is applied.

FIG. 18B is a diagram illustrating another example of the characteristic space divided into regions in a case where the region reduction rule according to the exemplary embodiment is applied.

FIG. 18C is a diagram illustrating another example of the characteristic space divided into regions in a case where the region reduction rule according to the exemplary embodiment is applied.

FIG. 19 is a diagram for describing a method of calculating a Pareto boundary to which the region reduction rule according to the exemplary embodiment is applied.

FIG. 20 is a diagram for describing a method of calculating a Pareto boundary to which the region reduction rule according to the exemplary embodiment is applied.

FIG. 21 is a diagram for describing a method of calculating a Pareto boundary to which the region reduction rule according to the exemplary embodiment is applied.

FIG. 22 is a diagram for describing a method of calculating a Pareto boundary to which the region reduction rule according to the exemplary embodiment is applied.

FIG. 23 is a diagram illustrating an example of a Pareto boundary in a case where there is no constraint condition according to the exemplary embodiment.

FIG. 24 is a diagram illustrating an example of an improvement region under the Pareto boundary illustrated in FIG. 23.

FIG. 25 is a diagram illustrating an example of a Pareto boundary in a case where there is a constraint condition according to the exemplary embodiment.

FIG. 26 is a diagram illustrating an example of an improvement region defined in a case where there is a constraint condition under the Pareto boundary illustrated in FIG. 25.

FIG. 27 is a view illustrating an example of a standard range and a management range according to the exemplary embodiment.

FIG. 28 is a diagram illustrating an example of evaluation value data according to the exemplary embodiment.

FIG. 29 is a diagram illustrating an example of evaluation value data after change displayed on the display unit according to the exemplary embodiment.

FIG. 30 is a diagram conceptually illustrating derivation of a predicted distribution by the Kalman filter according to the exemplary embodiment.

FIG. 31 is a view conceptually illustrating a relationship between a predicted distribution of a plurality of candidate control points and a standard range of product characteristics according to the exemplary embodiment.

FIG. 32A is a diagram for describing a control image of a control method 1 for setting an optimization target value to a standard center according to the exemplary embodiment.

FIG. 32B is a diagram for describing a control image of the control method 1 for setting the optimization target value to the standard center according to the exemplary embodiment.

FIG. 33 is a view conceptually illustrating an overshoot phenomenon and a hunting phenomenon.

FIG. 34 is a diagram conceptually illustrating a noise canceling effect which is a characteristic of a Kalman filter.

FIG. 35A is a diagram for describing a control image of a control method 2 for setting an optimization target value to upper and lower limits of a standard according to the exemplary embodiment.

FIG. 35B is a diagram for describing a control image of the control method 2 for setting the optimization target value to the upper and lower limits of the standard according to the exemplary embodiment.

FIG. 36A is a diagram for describing a control image of a control method 3 of gradually moving an optimization target value to a standard center according to the exemplary embodiment.

FIG. 36B is a diagram for describing a control image of the control method 3 of gradually moving the optimization target value to the standard center according to the exemplary embodiment.

FIG. 37 is a diagram for explaining that there are a plurality of candidates for an optimization target value in a case where the number of product characteristics according to the exemplary embodiment is two or more dimensions.

FIG. 38A is a diagram illustrating a combined active region in a case where the center does not coincide with the standard center according to the exemplary embodiment.

FIG. 38B is a diagram illustrating a combined active region in a case where the center coincides with the standard center according to the exemplary embodiment.

FIG. 39 is a diagram illustrating an example of a control result data sheet obtained when an optimal solution is searched according to an example of the exemplary embodiment.

FIG. 40A is a diagram illustrating a combined active region at a time point when control results up to the 26th control result in FIG. 39 are obtained.

FIG. 40B is a diagram illustrating a combined active region at a time point when the 27th control result in FIG. 39 is obtained.

### DESCRIPTION OF EMBODIMENT

### (Knowledge Underlying Present Invention)

The present inventors have found that the following problems arise in NPL 1 and NPL 2 described in the section of “BACKGROUND ART”.

There are several techniques proposed related to multi-objective Bayesian optimization for simultaneously optimizing a plurality of product characteristics. For example, NPL 1 described above discloses an optimal solution search principle and a specific calculation method of expected hypervolume improvement (EHVI), which is a type thereof. This makes it possible to perform quantitative evaluation of optimal solution search even when there are a plurality of product characteristics desired to optimize.

Furthermore, in industrial product development or manufacturing process development, there is a case where a standard range is provided as a constraint condition regarding the value of the product characteristic. For example, the standard range is “the battery capacity is desired to fall within the standard range of 1850 [mAh] to 1950 [mAh]”, “with 3 years as the minimum value, the longer the life is, the better it is (that is, the minimum value in the standard range of the life is 3 years, and the maximum value is +00)”, or the like. When the conventional Bayesian optimization is applied in a case where there is a standard range, there is a possibility that search has a poor calculation efficiency or a search proceeds to another region that is not the optimal solution.

Therefore, there are also some techniques proposed related to constrained Bayesian optimization. For example, the technique of PTL 1 includes, for each candidate control point, calculating, from a predictive distribution obtained by Gaussian process regression, a probability of falling within a standard range, extracting only the candidate control point whose probability exceeds a certain threshold, and evaluating an acquisition function. This corresponds to the constrained optimization problem.

Furthermore, for example, NPL 2 discloses expected hypervolume improvement with constraints (EHVIC) in which EHVI is extended in a case where there is a constraint condition. The design method of the acquisition function described in NPL 2 comprehensively indexes the probability of falling within the standard range and the improvement amount, and evaluates them for all candidate control points. Therefore, there is a high possibility of improving the search efficiency (that is, a true optimal solution is obtained).

Moreover, in the design method of an acquisition function of NPL 2, there is also a problem that a calculation amount increases in an exponential function order with respect to the number of product characteristics to be maximized or minimized and the number of Pareto points that are provisional optimal solutions (non-inferior solutions) in evaluating the acquisition function.

In addition, as described above, PTL 1 discloses a method of systematically executing adjustment of a gain value using PID control, which is one of modern control methods. However, since the method disclosed in PTL 1 is a rule-based gain adjustment method, quantitative evaluation is difficult, and it is not always possible to obtain a good control result capable of suppressing an overshoot phenomenon or a hunting phenomenon in control of time-series data at a mass production site. For this reason, in the control of the time-series data at the mass production site, the evaluation of the parameter becomes dependent on a person.

Meanwhile, a Kalman filter is widely known as a calculation method for estimating a state that changes in time series. The Kalman filter is a calculation method for estimating an invisible state inside the system by a mathematical model called a state space model. Therefore, the Kalman filter can be applied to control of time-series data at a mass production site on the basis of the estimated state information.

In view of the above, in the present disclosure, it is considered to use the state estimation by the Kalman filter and the idea of the acquisition function evaluation by the Bayesian optimization.

However, the occurrence of the overshoot phenomenon or the hunting phenomenon cannot be suppressed simply by combining the Kalman filter and the Bayesian optimization.

Therefore, an object of an evaluation device of the present disclosure is to quantitatively evaluate a candidate control point capable of suppressing occurrence of an overshoot phenomenon or a hunting phenomenon with respect to a control problem of time-series data.

An evaluation device according to an aspect of the present disclosure is an evaluation device that evaluates, by Bayesian optimization, a plurality of unknown characteristic points corresponding to a plurality of candidate control points at a second time following a first time based on a known characteristic point corresponding to a controlled control point at the first time, the evaluation device including: a first reception means that acquires control result data indicating the controlled control point at the first time and the known characteristic point at the first time; a second reception means that acquires purpose data indicating an optimization purpose, each of the plurality of unknown characteristic points indicating values of one or a plurality of product characteristics, and at least one product characteristic among the one or the plurality of product characteristics having the optimization purpose; a third reception means that acquires constraint condition data indicating a constraint condition applied to the at least one product characteristic; a fourth reception means that acquires region reduction rule data indicating a division method of a characteristic space represented by the at least one product characteristic and indicating a dimension for reducing an active region for each region of the characteristic space divided by the division method; a calculation means that calculates an evaluation value of each of the plurality of unknown characteristic points based on the control result data, the purpose data, the constraint condition data, and the region reduction rule data; and an output means that outputs the evaluation value, in which the calculation means applies weighting according to a degree of conformity of the constraint condition to the evaluation value for the at least one product characteristic.

As a result, the calculation means calculates evaluation values of a plurality of unknown characteristic points at a second time following a first time on the basis of the control result data, the purpose data, the constraint condition data, and the region reduction rule data. When the evaluation values of the plurality of unknown characteristic points are calculated, weighting according to the degree of conformity of the constraint condition is applied to the evaluation value for at least one product characteristic, and the at least one product characteristic has an optimization purpose. Therefore, the Kalman filter and the Bayesian optimization can be applied to an optimization problem in which a constraint condition is applied to time-series product characteristics having a purpose of the optimization problem. In this way, since the evaluation values of the plurality of unknown characteristic points can be calculated from the known characteristic points corresponding to the controlled control points at the first time as the past control result information, the candidate control points to be set next can be quantitatively analyzed.

As described above, according to the analysis system of the present invention, the optimal candidate control point to be set next can be quantitatively calculated, and realization of highly accurate control can be expected regardless of the ability of the analyst.

The constraint condition may be at least one constraint range. The optimization purpose may include a first purpose of keeping the product characteristic within any one of the at least one constraint range and a second purpose of minimizing or maximizing the product characteristic. The calculation means may calculate the evaluation value by performing different weighting processing in the following cases (i) to (iii) for each of at least one product characteristic.

(i) when an interval of the product characteristic used to calculate the evaluation value is outside each of the at least one constraint range.

(ii) when the interval is within any one of the at least one constraint range, and the optimization purpose is the first purpose.

(ii) when the interval is within any one of the at least one constraint range, and the optimization purpose is the second purpose.

For example, the plurality of constraint ranges are a standard range and a management range included in the standard range. Then, the case of (ii) is divided into a first case where the interval is within the standard range and out of the management range and the optimization purpose is the first purpose, and a second case where the interval is within the management range and the optimization purpose is the first purpose. Furthermore, for example, the weighting processing using a larger weight is performed in the second case than in the first case. As described above, there are a plurality of constraint ranges, and by further dividing the case (ii) into a plurality of cases, weighting can be performed on each of the plurality of constraint ranges in a stepwise manner. Therefore, even in a case where the value of the product characteristic falls within the standard range and is desired to fall within the management range as much as possible, the evaluation value can be appropriately calculated. As a result, it is possible to further extend the application scene for the optimization problem.

The evaluation device may further include a candidate control point creating means that creates the plurality of candidate control points by combining values that satisfy predetermined conditions of the plurality of process conditions.

For example, the predetermined condition is a condition that the sum of values of ratio variables of the plurality of process conditions is 1. In a more specific example, the ratio variable is a compounding ratio of materials such as compounds corresponding to the process conditions. Therefore, for each combination of compounding ratios of a plurality of kinds of compounds, an evaluation value for the combination can be calculated. As a result, an optimal solution for at least one product characteristic of the synthetic material obtained by compounding these compounds can be appropriately searched.

Furthermore, the calculation means may calculate the evaluation value based on a constraint range having a shape different from a rectangle of the at least one constraint range.

As a result, for example, in the characteristic space represented by two product characteristics, the evaluation value is calculated based on the constraint range such as a circle, an ellipse, or a star. Therefore, the shape of the constraint range is not limited to a rectangular shape, and the application scene can be further expanded.

The calculation means may calculate a predicted distribution at the plurality of candidate control points using a Kalman filter, and calculate the evaluation value using the calculated predicted distribution.

As a result, it is possible to sequentially calculate the predicted distribution obtained by the Kalman filter and the evaluation value obtained from the predicted distribution by using the Bayesian optimization. Therefore, the candidate control point to be set as the control point next can be selected based on the evaluation value. That is, since the evaluation value calculated for each candidate control point is output, the user of the evaluation device can select the candidate control point as the next control point based on the evaluation values, and use the characteristic point obtained by the control using the control point for the calculation of the evaluation value of each candidate control point. By repetition of such a control and calculation and output of an evaluation value, it is possible to obtain a solution of a candidate control point that satisfies an optimization purpose of each product characteristic, that is, an optimal solution.

Furthermore, the calculation means may calculate the evaluation value using a Monte Carlo method.

As a result, since the Monte Carlo method is an approximate method, the evaluation value can be calculated approximately even when it is difficult to calculate the evaluation value analytically.

Hereinafter, exemplary embodiments will be specifically described with reference to the drawings.

Note that the exemplary embodiments described below illustrate comprehensive or specific examples. Numerical values, shapes, materials, constituent elements, disposition positions and connection modes of the constituent elements, steps, order of the steps, and the like illustrated in the following exemplary embodiments are merely examples, and therefore are not intended to limit the present disclosure. Further, among the constituent elements in the following exemplary embodiments, constituent elements not recited in the independent claims are described as arbitrary constituent elements. Furthermore, each of the drawings is a schematic view, and is not necessarily illustrated precisely. In addition, in the drawings, same reference marks are given to the same constituent members.

### First Exemplary Embodiment

### [Outline]

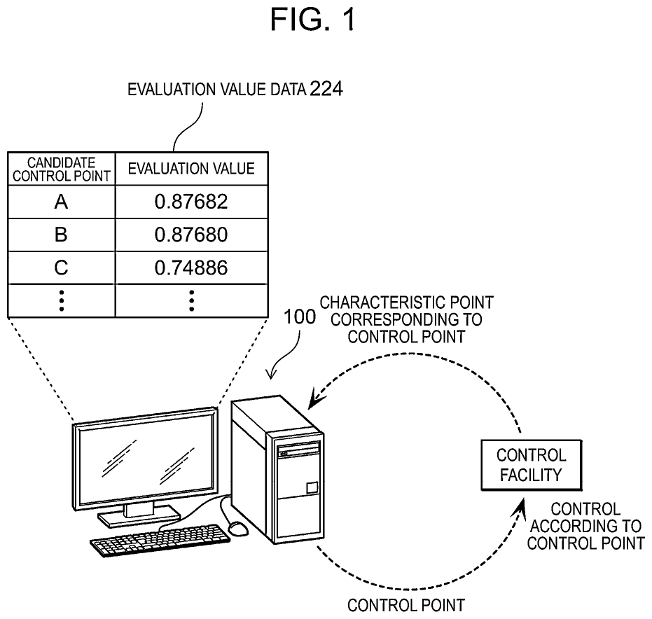

FIG. 1 is a diagram for explaining a schematic operation of an evaluation device according to the present exemplary embodiment.

Evaluation device 100 in the present exemplary embodiment calculates an evaluation value for each of a plurality of candidate control points, and displays evaluation value data 224 indicating those evaluation values. The candidate control point is a point that is a candidate for the control point. The control point is a point on a control space indicating a control condition (combination of values of each process condition on the control space). The evaluation value is a value indicating an evaluation result of a product characteristic predicted to be obtained by a control according to the candidate control point. For example, the evaluation value indicates a degree to which the product characteristic predicted to be obtained by the control matches an optimization purpose, and the larger the evaluation value is, the larger the degree is.

With reference to the evaluation value of each candidate control point indicated by evaluation value data 224, the user selects one of those candidate control points as a next control point. The user performs control according to the selected control point using a control facility (mass production facility). Through the control, a characteristic point corresponding to the control point is obtained. The characteristic point indicates, for example, the value of a product characteristic, and where there are a plurality of product characteristics, the characteristic point is indicated as a combination of the values of the plurality of product characteristics. The user inputs the obtained characteristic point into evaluation device 100 in association with a control point. As a result, evaluation device 100 calculates evaluation values for the candidate control points again using the characteristic points obtained by the control, and displays evaluation value data 224 indicating the evaluation values again. That is, evaluation value data 224 is updated. By repeating such update of evaluation value data 224, evaluation device 100 searches for an optimal solution of the product characteristic.

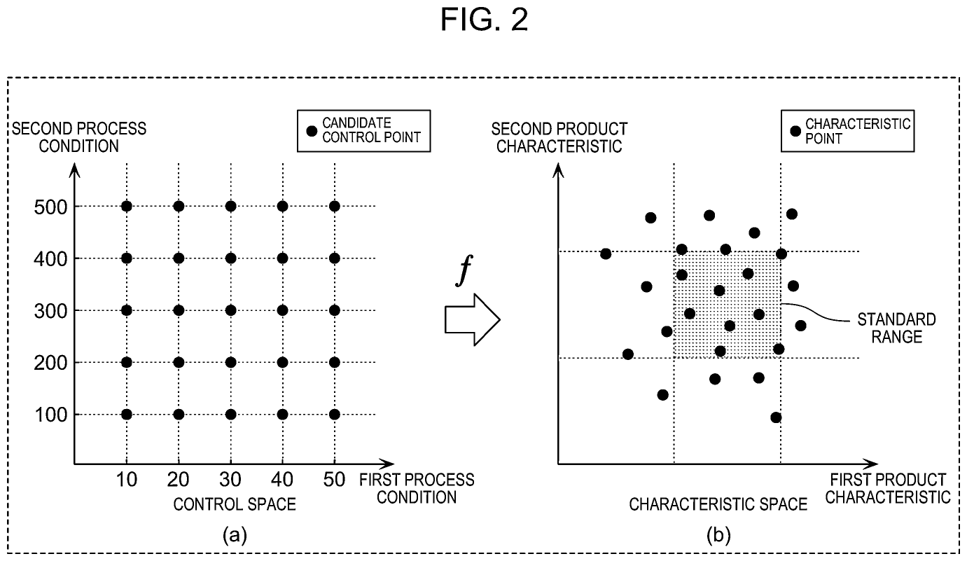

FIG. 2 is a diagram illustrating an example in which each candidate control point and each characteristic point are graphically represented. Specifically, the graph in part (a) of FIG. 2 illustrates candidate control points arranged in the control space, and the graph in part (b) of FIG. 2 illustrates characteristic points arranged in the characteristic space.

As illustrated in part (a) of FIG. 2, the candidate control points in the control space are arranged on grid points corresponding to a combination of values of the first process condition and the second process condition. The characteristic point corresponding to each candidate control point illustrated in part (a) of FIG. 2 is arranged in the characteristic space as illustrated in part (b) of FIG. 2. Specifically, when the candidate control point is selected as the control point, and the respective values of a first product characteristic and a second product characteristic are obtained through the control according to the control point, the characteristic point corresponding to the control point is arranged at a position represented by a combination of the value of the first product characteristic and the value of the second product characteristic. Here, there is a one-to-one correspondence between the candidate control point and the characteristic point, but the correspondence (that is, the function f in FIG. 2) is unknown.

Executing a control once can be rephrased as selecting one candidate control point and acquiring one set of correspondence relationship with the characteristic point corresponding to the selected candidate control point.

In addition, as illustrated in (b) of FIG. 2, the characteristic space is divided into an in-standard-range region and an out-of-standard-range region by the set standard range. Furthermore, in the present exemplary embodiment, a constraint condition that is a standard range may be applied to a product characteristic having the optimization purpose. The constraint condition is a condition applied to the product characteristic, and for example, there is a constraint range designating a range of the value of a product characteristic as a condition. Examples of the constraint range include a standard range defined by a product characteristic standard, a management range that can be appropriately set by a user, and the like.

In the present exemplary embodiment, an example in which the number of process conditions is two as in the first process condition and the second process condition and the number of product characteristics is two as in the first product characteristic and the second product characteristic will be mainly described, but the number of process conditions and the number of product characteristics are not limited to two. The number of process conditions may be one or three or more, and the number of product characteristics may be one or three or more. The number of process conditions and the number of product characteristics may be equal or different.

In the present exemplary embodiment, the correspondence does not need to be universal, and it is assumed that the correspondence depends on the control result one time point before and changes in time series.

In evaluation device 100, the correspondence relationship between the candidate control point and the characteristic point is described by a Kalman filter.

Hereinafter, the Kalman filter used in evaluation device 100 will be described.

### <Kalman Filter>

The Kalman filter is a calculation method for estimating an invisible state inside the system by a mathematical model called a state space model. In other words, the Kalman filter is a calculation method for estimating a state quantity in a system that changes with time from an observation value including an error, and is included in a framework based on Bayesian statistics.

In the mathematical model of the Kalman filter, when the internal state quantity of the system at time t is X₍ₜ₎ and the observation amount at time t is Y₍ₜ₎, the internal state quantity of the system that changes with time can be expressed by (Equation 1).

$$\begin{matrix}[ Math . 1 ] & \\ \begin{matrix}{X}_{( t + 1 )} = {AX}_{( t )} + B υ \\ {Y}_{( t )} = {CW}_{( t )} + {w}_{( t )}\end{matrix} & ( Equation 1 )\end{matrix}$$

Here, A, B, and C represent matrices that define conversion. v₍ₜ₎ and w₍ₜ₎ represent Gaussian noise at time t. The average and variance of the Gaussian noise can be appropriately set by the analyst, for example, set to 0 and 1.

Note that the above equation of (Equation 1) is also referred to as a state equation and describes temporal evolution of an internal state of a system that is not observed. The following equation of (Equation 1) is also referred to as an observation equation, and describes the conversion from the internal state of the system to the observation amount observed by us. When all the internal state quantities of the system are observed, C may be used as the identity matrix. Since the value of each element of A, B, and C is usually unknown, it is also possible to proceed while sequentially estimating by a time-series analysis method such as an autoregressive model.

The Kalman filter formulated based on (Equation 1) above is referred to as a linear Gaussian filter. In the linear Gaussian filter, the internal state quantity at the next time point predicted from the observed state quantity is derived using the predicted distribution as shown in (Equation 2).

$$\begin{matrix}[ Math . 2 ] & \\ p ( {X}_{( t )} \vert {Y}_{( 1 : t - 1 )} ) ( {X}_{( t )}^{-} , {P}_{( t )}^{-} ) & ( Equation 2 )\end{matrix}$$

Here, Y_{(1:t-1)} represents a vector obtained by collecting Y from time 1 to time t−1. In addition, the average and variance of the normal distribution on the right side of (Equation 2) are calculated by solving the following five update equations (Equation 3) at each time.

$$\begin{matrix}[ Math . 3 ] & \\ \begin{matrix}{X}_{( t )}^{-} = A {\hat{X}}_{( t - 1 )} \\ {P}_{( t )}^{-} = {AP}_{( t - 1 )} {A}^{T} + {BQB}^{T} \\ {G}_{( t )} = {P}_{( t )}^{-} {{C}^{T} ( {CP}_{( t )}^{-} {C}^{T} + R )}^{- 1} \\ {\hat{X}}_{( t )} = {\hat{X}}_{( t )}^{-} + {G}_{( t )} ( {Y}_{( t )} - C {\hat{X}}_{( t )}^{-} ) \\ {P}_{( t )} = ( I - {G}_{( t )} C ) {P}_{( t )}^{-}\end{matrix} & ( Equation 3 )\end{matrix}$$

Note that the Kalman filter includes, for example, an Ensemble Kalman Filter (EnKF), an Extended Kalman Filter (EKF), an Unscented Kalman Filter (UKF), a particle filter, and the like, and there are various patterns depending on a case where the conversion is nonlinear, a case where the noise is a non-Gaussian distribution, a case where the noise is influenced by an external input, and the like. That is, the form of the Kalman filter in the present exemplary embodiment may be any of the above patterns and is not particularly specified. In addition, if the correspondence relationship between the candidate control points and the characteristic points can be estimated with some probability distribution, a method other than the Kalman filter may be used.

Hereinafter, in order to simplify the description, a Kalman filter of a linear Gaussian form in which control points and characteristic points are collectively treated as an internal state will be described as an example.

When the candidate control point vector X=(X₁, . . . , X_{Dx}) and the characteristic point vector Y=(Y₁, . . . , Y_{Dy}) are collectively expressed as Z=(X₁, . . . , X_{Dx}, Y₁, . . . , Y_{Dy}), the state equation and the observation equation shown in (Equation 1) are described as in (Equation 4) below.

$$\begin{matrix}[ Math . 4 ] & \\ \begin{matrix}{Z}_{interior ( t + 1 )} = {AZ}_{interior ( t )} + B {υ}_{( t )} \\ {Z}_{observation ( t )} = {CZ}_{interior ( t )} + w ( t )\end{matrix} & ( Equation 4 )\end{matrix}$$

In the Kalman filter formulated as in (Equation 4), if the Z_{observation(t)} is substituted for Y₍ₜ₎ in the fourth update equation of (Equation 3), the predicted distribution of the internal state quantity of Z is sequentially calculated.

Here, the multidimensional normal distribution has a property that normality is preserved even when a conditioning operation is performed in some dimensions. By using this property, the predicted distribution of the target characteristic Y as the product characteristic under the condition that the control factor X as the process condition is given is derived as the normal distribution. The average and variance of the normal distribution are specifically given by (Equation 5).

$$\begin{matrix}[ Math . 5 ] & \\ \begin{matrix}( AVERAGE ) = {A}_{Y} {Z}_{( t )} + {{P}_{YX ( t )}^{-} ( {P}_{XX ( t )}^{-} )}^{- 1} {X}_{( t )} \\ ( VARIANCE ) = {P}_{YY ( t )}^{-} - {{P}_{YX ( t )}^{-} ( {P}_{XX ( t )}^{-} )}^{- 1} {P}_{XY ( t )}^{-}\end{matrix} & ( Equation 5 )\end{matrix}$$

where,

[Math. 6]

Ż(t)

and

[Math. 7]

P⁻₍ₜ₎

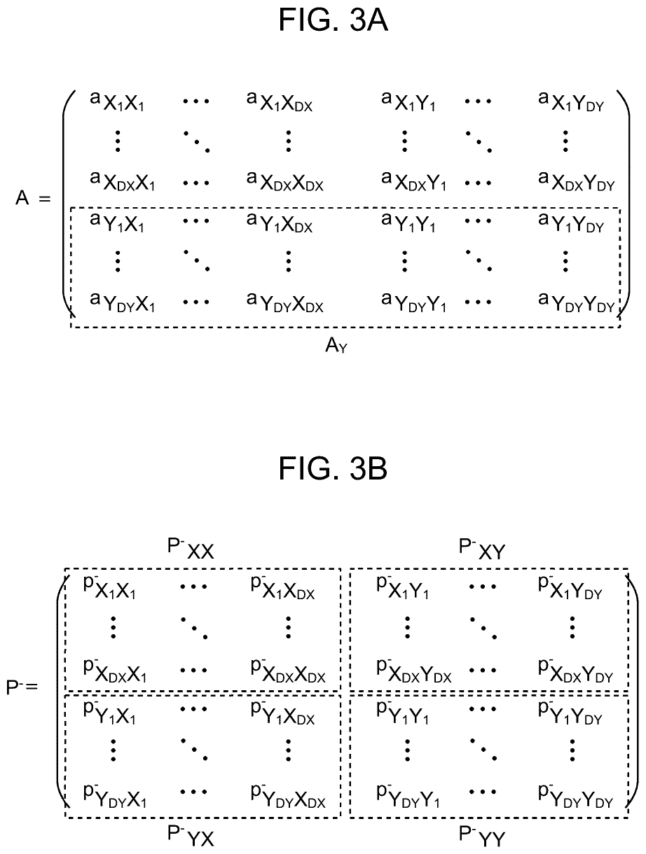

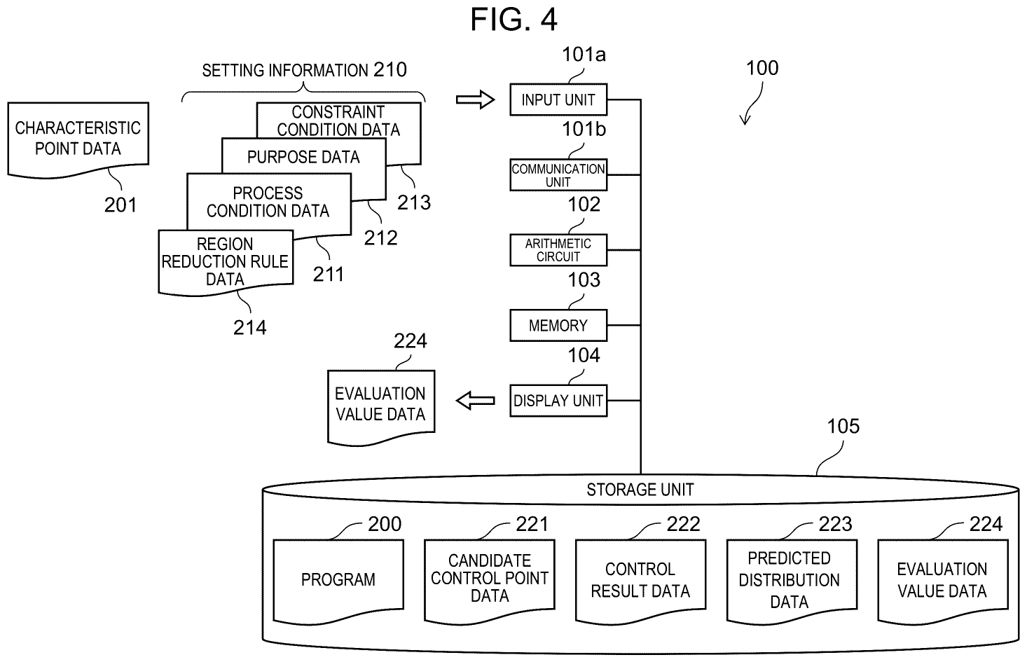

Let be an amount calculated using (Equation 3), and A_{Y}, P⁻_{XX}, P⁻_{XY}, P⁻_{YY}, and P⁻_{YX} represent a submatrix from which some elements of the matrix are extracted as illustrated in FIGS. 3A and 3B. FIGS. 3A and 3B are diagrams illustrating submatrices. FIG. 3A illustrates elements of a matrix A that defines conversion and a submatrix A_{Y} thereof. FIG. 3B illustrates elements of the matrix P⁻ and submatrices P⁻_{XX}, P⁻_{XY}, P⁻_{YY}, and P⁻_{YX} thereof.

[Hardware configuration] FIG. 4 is a diagram illustrating a configuration of evaluation device 100 according to the present exemplary embodiment.

Evaluation device 100 includes input unit 101a, communication unit 101b, arithmetic circuit 102, memory 103, display unit 104, and storage unit 105.

Input unit 101a is a human machine interface (HMI) that receives an input operation by the user. Input unit 101a is, for example, a keyboard, a mouse, a touch sensor, a touchpad, or the like.

For example, input unit 101a receives setting information 210 as an input from the user. Setting information 210 includes process condition data 211, purpose data 212, constraint condition data 213, and region reduction rule data 214. Process condition data 211 is, for example, data indicating a possible value of the process condition as illustrated in part (a) of FIG. 2. The value of the process condition may be a continuous value or a discrete value. Purpose data 212 is, for example, data indicating an optimization purpose of a product characteristic such as minimization or maximization. Constraint condition data 213 is, for example, data indicating a constraint condition such as a constraint range. Region reduction rule data 214 is data indicating a rule for calculating the pareto boundary, and changes the method of calculating the improvement amount. More specifically, region reduction rule data 214 indicates a division method of the characteristic space represented by at least two product characteristics, and indicates a dimension for reducing the active region for each region of the characteristic space divided by the division method. Details will be described later.

Communication unit 101b is connected to another device in a wired or wireless manner, and transmits and receives data to and from the other device. For example, communication unit 101b receives characteristic point data 201 from another device (for example, a control device).

Display unit 104 displays an image, a character, or the like. Display unit 104 is, for example, a liquid crystal display, a plasma display, an organic electro-luminescence (EL) display, or the like. Note that display unit 104 may be a touch panel integrated with input unit 101a.

Storage unit 105 stores program (that is, computer program) 200 in which each command to arithmetic circuit 102 is described and various types of data. Storage unit 105 is a nonvolatile recording medium, and is, for example, a magnetic storage device such as a hard disk, a semiconductor memory such as a solid state drive (SSD), an optical disk, or the like.

Note that program 200 and various types of data may be provided from the above-described other devices to evaluation device 100 via communication unit 101b and stored in storage unit 105, for example. Storage unit 105 stores, as various types of data, candidate control point data 221, control result data 222, predicted distribution data 223, and evaluation value data 224.

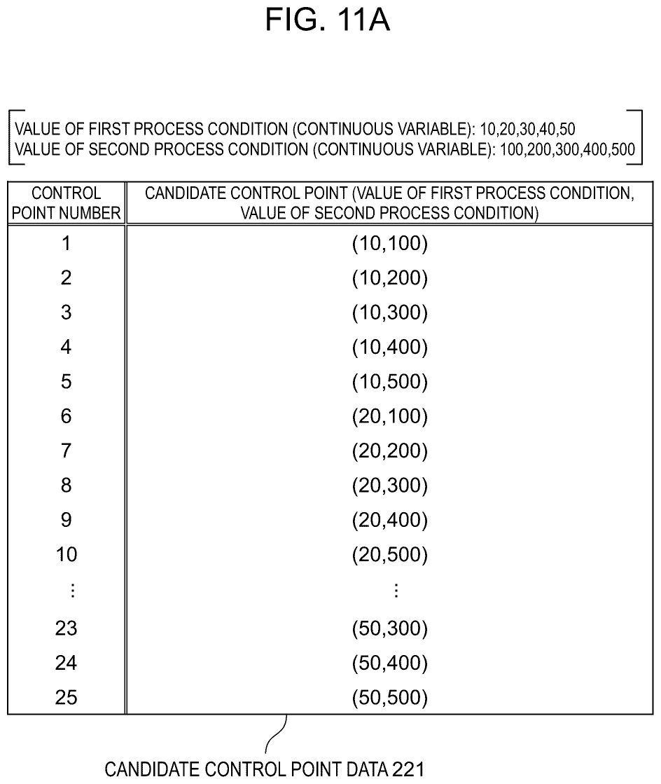

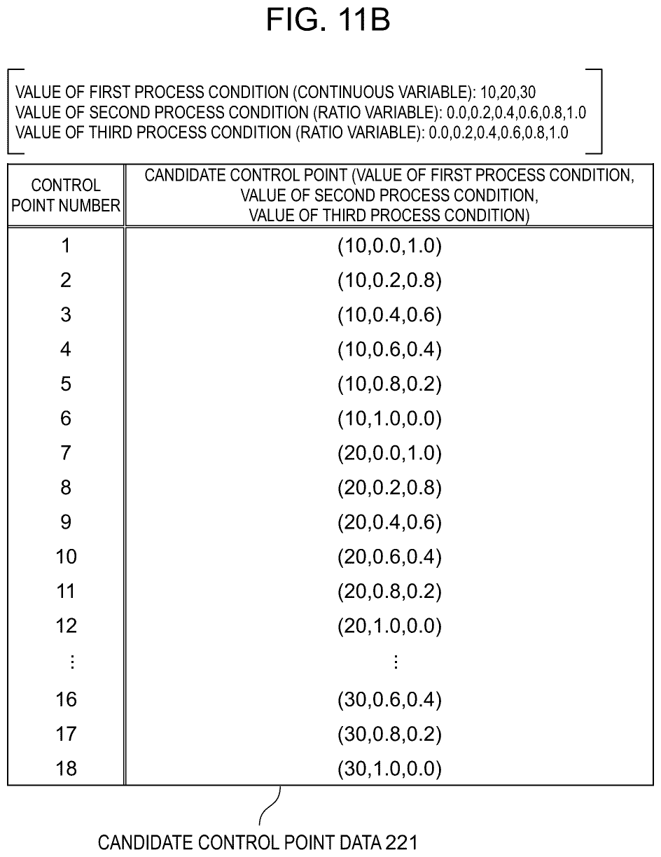

Candidate control point data 221 is data indicating each candidate control point. In the example illustrated in part (a) of FIG. 2, each candidate control point is represented by a combination of values of the first process condition and the second process condition. Candidate control point data 221 may be data in a table format in which combinations of values of the first process condition and the second process condition are listed. A specific example of such candidate control point data 221 will be described in detail with reference to FIGS. 11A and 11B.

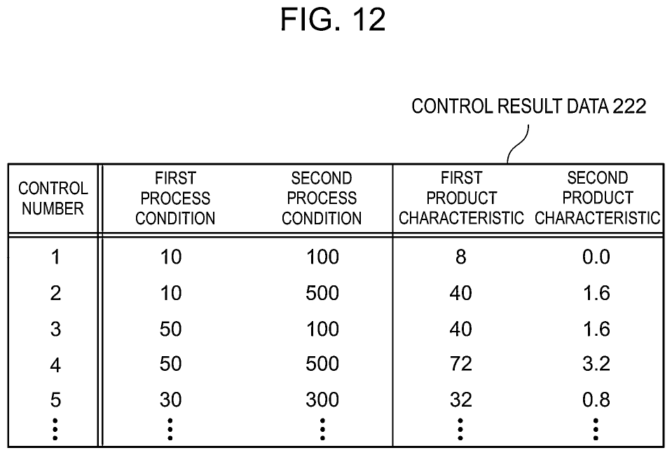

Control result data 222 is data indicating one or more control points used in a control and characteristic points respectively corresponding to the one or more control points. For example, control result data 222 indicates a combination of a control point on the control space in part (a) of FIG. 2 and a characteristic point on the characteristic space in part (b) of FIG. 2 obtained by a control using the control point. The control point is represented by a combination of values of the first process condition and the second process condition. The characteristic point is represented by a combination of values of the first product characteristic and the second product characteristic. Control result data 222 may be data in a table format in which combinations of the control points and the characteristic points are listed. A specific example of control result data 222 will be described in detail with reference to FIG. 12.

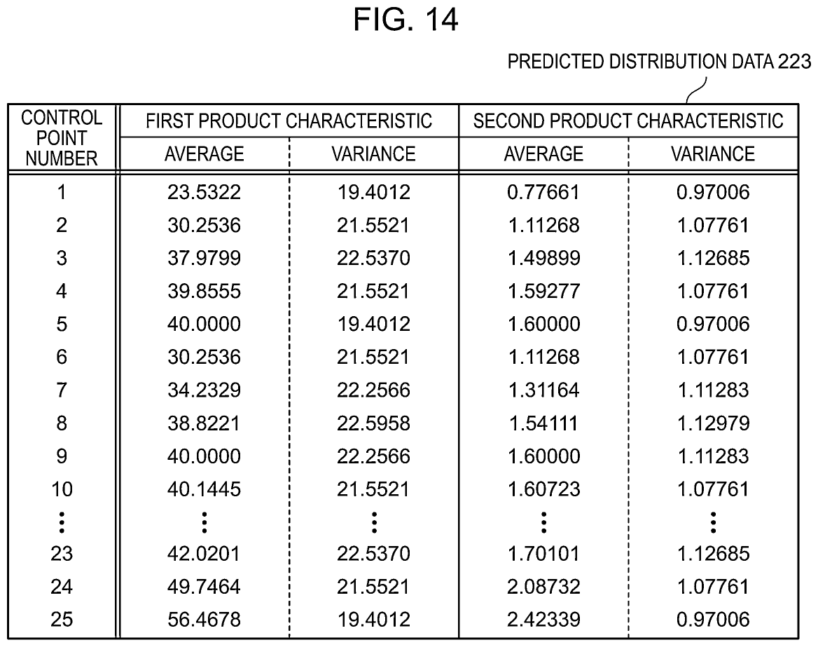

Predicted distribution data 223 is data indicating the predicted distribution of all the candidate control points indicated by candidate control point data 221. The predicted distribution is a distribution obtained by (Equation 3) based on the Kalman filter as described above, and is represented by, for example, an average and a variance. For example, predicted distribution data 223 may be data in a table format indicating the predicted distribution of the first product characteristic and the predicted distribution of the second product characteristic in association with each candidate control point. A specific example of predicted distribution data 223 will be described in detail with reference to FIG. 14.

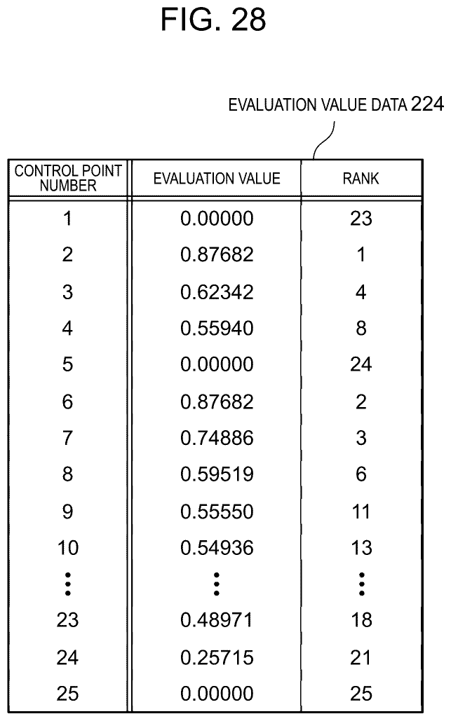

For example, as illustrated in FIG. 1, evaluation value data 224 is data indicating an evaluation value for each of the plurality of candidate control points. For example, evaluation value data 224 may be data in a table format indicating the evaluation value in association with each of the plurality of candidate control points. Another specific example of evaluation value data 224 will be described in detail with reference to FIG. 28 and the like.

Arithmetic circuit 102 is a circuit that reads program 200 from storage unit 105 to memory 103 and executes expanded program 200. Arithmetic circuit 102 is, for example, a central processing unit (CPU), a graphics processing unit (GPU), or the like.

### [Functional Configuration]

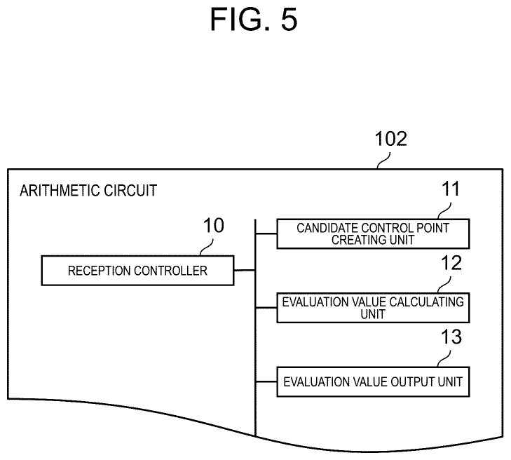

FIG. 5 is a block diagram illustrating a functional configuration of arithmetic circuit 102.

Arithmetic circuit 102 implements a plurality of functions for generating evaluation value data 224 by executing program 200. Specifically, arithmetic circuit 102 includes reception controller (first reception means, second reception means, third reception means, and fourth reception means) 10, candidate control point creating unit (candidate control point creating means) 11, evaluation value calculating unit (calculation means) 12, and evaluation value output unit (output means) 13.

### <Reception Controller 10>

Reception controller 10 receives characteristic point data 201, process condition data 211, purpose data 212, constraint condition data 213, and region reduction rule data 214 via input unit 101a or communication unit 101b. For example, when characteristic point data 201 is input by an input operation to input unit 101a by the user, reception controller 10 writes the characteristic point indicated in characteristic point data 201 in control result data 222 of storage unit 105 in association with the control point. As a result, control result data 222 is updated. When control result data 222 is updated, reception controller 10 causes evaluation value calculating unit 12 to execute processing using updated control result data 222. That is, reception controller 10 causes evaluation value calculating unit 12 to execute calculation of the evaluation value. Note that, at this time, evaluation value calculating unit 12 executes calculation of the evaluation value using candidate control point data 221 already stored in storage unit 105. In this manner, reception controller 10 causes evaluation value calculating unit 12 to start the calculation of the evaluation value with the input of characteristic point data 201 as a trigger.

Furthermore, reception controller 10 may cause evaluation value calculating unit 12 to start calculation of the evaluation value in response to another trigger. For example, when control result data 222 has already been stored in storage unit 105, reception controller 10 may cause evaluation value calculating unit 12 to start the calculation of the evaluation value with the input of the level of the control point by the user as a trigger. The level of the control point is, for example, a minimum value, a maximum value, a discrete width, and the like of values that can be taken by the process condition. That is, when the level of the control point is input by the user and candidate control point data 221 is generated based on the level, reception controller 10 causes evaluation value calculating unit 12 to start the calculation of the evaluation value based on candidate control point data 221, control result data 222, and region reduction rule data 214.

Alternatively, when candidate control point data 221 has already been stored in storage unit 105, reception controller 10 may cause evaluation value calculating unit 12 to start the calculation of the evaluation value with the input of control result data 222 by the user as a trigger. When control result data 222 is input by the user, reception controller 10 causes evaluation value calculating unit 12 to start calculation of an evaluation value based on control result data 222, candidate control point data 221, and region reduction rule data 214.

Alternatively, when candidate control point data 221 has already been stored in storage unit 105, reception controller 10 may cause evaluation value calculating unit 12 to start the calculation of the evaluation value with the reception of control result data 222 by communication unit 101b as a trigger. For example, a control facility, a control device, a manufacturing device, or the like transmits control result data 222 to evaluation device 100, and communication unit 101b receives control result data 222. When control result data 222 is received by communication unit 101b, reception controller 10 causes evaluation value calculating unit 12 to start calculation of an evaluation value based on control result data 222, candidate control point data 221, and region reduction rule data 214.

As described above, when there are candidate control point data 221 and control result data 222, reception controller 10 causes evaluation value calculating unit 12 to start calculation of the evaluation value based on them. When control result data 222 has already been stored in storage unit 105, reception controller 10 may cause evaluation value calculating unit 12 to start the calculation of the evaluation value with the input of candidate control point data 221 by the user as a trigger. When candidate control point data 221 and control result data 222 have already been stored in storage unit 105, reception controller 10 may cause evaluation value calculating unit 12 to start the calculation of the evaluation value with an input of a start instruction by the user as a trigger.

### <Candidate Control Point Creating Unit 11>

Candidate control point creating unit 11 generates candidate control point data 221 based on process condition data 211 acquired by reception controller 10. In other words, candidate control point creating unit 11 creates a plurality of candidate control points by combining values that satisfy predetermined conditions of the plurality of process conditions. In the present exemplary embodiment, candidate control point creating unit 11 creates each of the plurality of candidate control points using a value of each of one or more process conditions. Candidate control point creating unit 11 then stores generated candidate control point data 221 in storage unit 105.

### <Evaluation Value Calculating Unit 12>

Evaluation value calculating unit 12 reads candidate control point data 221 and control result data 222 from storage unit 105, generates predicted distribution data 223 based on these pieces of data, and stores predicted distribution data 223 in storage unit 105. Further, evaluation value calculating unit 12 generates evaluation value data 224 on the basis of predicted distribution data 223, purpose data 212, constraint condition data 213, and region reduction rule data 214 acquired by reception controller 10, and stores evaluation value data 224 in storage unit 105.

In the present exemplary embodiment, evaluation value calculating unit 12 calculates a predicted distribution at a plurality of candidate control points using the Kalman filter, and calculates an evaluation value using the calculated predicted distribution. Note that, as will be described later, evaluation value calculating unit 12 may calculate the evaluation value on the basis of a constraint range having a shape different from a rectangle among at least one constraint range.

### <Evaluation Value Output Unit 13>

Evaluation value output unit 13 reads evaluation value data 224 from storage unit 105 and outputs evaluation value data 224 to display unit 104. Alternatively, evaluation value output unit 13 may output evaluation value data 224 to an external device via communication unit 101b. That is, evaluation value output unit 13 outputs the evaluation value of each candidate control point. Note that evaluation value output unit 13 may directly acquire evaluation value data 224 from evaluation value calculating unit 12 and output the evaluation value data 224 to display unit 104. Similarly, evaluation value output unit 13 reads predicted distribution data 223 from storage unit 105 and outputs predicted distribution data 223 to display unit 104. Note that evaluation value output unit 13 may directly acquire predicted distribution data 223 from evaluation value calculating unit 12 and output predicted distribution data 223 to display unit 104.

### [Input]

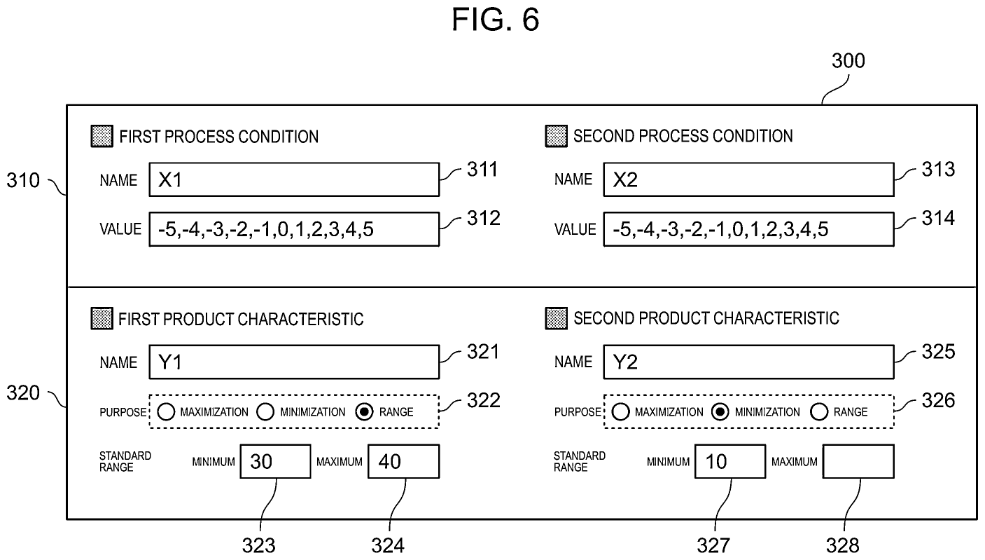

FIG. 6 is a diagram illustrating an example of a reception image displayed on display unit 104 to receive the input of setting information 210.

Reception image 300 includes process condition region 310 and product characteristic region 320. Process condition region 310 is a region for receiving an input of process condition data 211. Product characteristic region 320 is a region for receiving input of purpose data 212 and constraint condition data 213.

### <Process Condition Region 310>

Process condition region 310 has input fields 311 to 314. Input field 311 is a field for inputting the name of the first process condition. For example, in input field 311, “X1” is input as the name of the first process condition. Input field 312 is a field for inputting a value of the first process condition. For example, in input field 312, “−5, −4, −3, −2, −1, 0, 1, 2, 3, 4, 5” is input as the value of the first process condition. Similarly, input field 313 is a field for inputting the name of the second process condition. For example, in input field 313, “X2” is input as the name of the second process condition. Input field 314 is a field for inputting the value of the second process condition. For example, in input field 314, “−5, −4, −3, −2, −1, 0, 1, 2, 3, 4, 5” is input as the value of the second process condition.

With such an input to input fields 311 to 314, process condition data 211 corresponding to the input result is input to evaluation device 100.

### <Product Characteristic Region 320>

Product characteristic region 320 has input fields 321 to 328. Input fields 321 and 325 are fields for inputting the name of the first product characteristic and the name of the second product characteristic. For example, “Y1” is input as the name of the first product characteristic in input field 321, and “Y2” is input as the name of the second product characteristic in input field 325. Input fields 322 and 326 are fields for selecting an optimization purpose of the first product characteristic and the second product characteristic. Specifically, each of input fields 322 and 326 has three radio buttons for selecting for the purpose of any one of “maximization”, “minimization”, and “within standard range”. The purpose of “maximization” is to maximize the value of the first product characteristic or the second product characteristic, and the purpose of “minimization” is to minimize the value of the first product characteristic or the second product characteristic. The purpose of “within standard range” is to make the value of the first product characteristic or the second product characteristic fall within the standard range. For example, when the radio button indicating “within standard range” is selected by the input operation on input unit 101a by the user, evaluation device 100 selects within standard range as the optimization purpose of the first product characteristic or the second product characteristic. Input fields 323 and 324 are fields for inputting the minimum value and the maximum value, respectively, indicating the standard range of the first product characteristic. For example, in a case where “30” is input as the minimum value in input field 323 and “40” is input as the maximum value in input field 324, evaluation device 100 sets the standard range to 30 to 40. Input fields 327 and 328 are fields for inputting the minimum value and the maximum value, respectively, in the standard range of the second product characteristic. For example, in a case where “10” is input as the minimum value in the standard range to input field 327 and none is input to input field 328, evaluation device 100 sets the standard range to 10 to +∞. When none is input to input field 327, evaluation device 100 sets the minimum value in the standard range to −∞.

By such input to input fields 321 to 328, purpose data 212 and constraint condition data 213 corresponding to the input result are input to evaluation device 100. That is, reception controller 10 acquires purpose data 212 according to the inputs to input fields 322 and 326, and acquires constraint condition data 213 according to the inputs to input fields 323, 324, 327, and 328. In the example of FIG. 6, purpose data 212 indicates that the value of the first product characteristic falls within the standard range as the optimization purpose of the first product characteristic, and indicates the minimization of the value of the second product characteristic as the optimization purpose of the second product characteristic. Further, constraint condition data 213 indicates that the standard range of the first product characteristic is 30 to 40, and the standard range of the second product characteristic is 10 to +∞.

### <Region Reduction Rule Region 330>

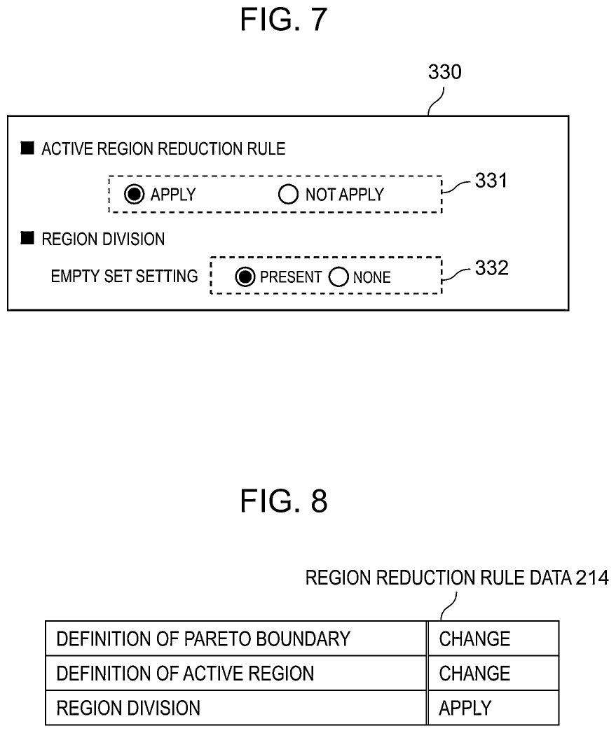

FIG. 7 is a diagram illustrating an example of a reception image displayed on display unit 104 to receive the input of region reduction rule data 214.

Reception image 300 includes region reduction rule region 330 illustrated in FIG. 7 in addition to process condition region 310 and product characteristic region 320 illustrated in FIG. 6. Region reduction rule region 330 is a region for receiving an input of region reduction rule data 214.

Region reduction rule region 330 has input fields 331 and 332. Input field 331 is a field for inputting whether to apply the region reduction rule. Input field 332 is a field for inputting whether to include an empty set in the region division when the region reduction rule is applied. Specifically, input field 331 has two radio buttons for selecting whether to “apply” or “not apply” the region reduction rule. Furthermore, input field 332 has two radio buttons for selecting “present” or “none” indicating whether to perform empty set setting in region division.

For example, in a case where the radio button indicating “apply” is selected by the input operation to input unit 101a by the user, evaluation device 100 applies the region reduction rule in the evaluation value calculation processing. Furthermore, in a case where the radio button indicating “apply” is selected by the input operation to input unit 101a by the user, evaluation device 100 calculates the volume of the improvement region by applying the region reduction rule after performing the region division including the empty set in the calculation processing of the evaluation value.

### <Example of Region Reduction Rule Data 214>

FIG. 8 is a diagram illustrating an example of region reduction rule data 214.

Region reduction rule data 214 input by region reduction rule region 330 of reception image 300 in FIG. 7 indicates that the definition of the pareto boundary is changed, the definition of the active region is changed, and the region division is applied, for example, as illustrated in FIG. 8. As a result, the method of calculating the improvement amount is changed. Note that a specific example of the changed definition and the applied region division will be described later, and thus the description thereof will be omitted here.

Note that the value of the process condition included in process condition data 211 may be an absolute value, or may be a relative value such as a ratio with respect to a sum of values of other process conditions or values of all process conditions. In addition, the value of the continuous variable of the first process condition, the value of the ratio variable of the second process condition, and the value of the ratio variable of the third process condition may be indicated. The variable includes a discrete variable different from the continuous variable. When the process condition is a discrete variable, the discrete variable does not have a magnitude relationship and a numerical magnitude such as “apple, orange, banana” or “with catalyst, without catalyst”. The ratio variable indicates, for example, the compounding ratio of the material under the first process condition or the second process condition in the synthetic material generated by compounding the material under the first process condition and the material under the second process condition.

Purpose data 212 indicates, for example, an optimization purpose of the first product characteristic and an optimization purpose of the second product characteristic. Constraint condition data 213 input by product characteristic region 320 of reception image 300 in FIG. 6 may indicate the standard range of the first product characteristic and the standard range of the second product characteristic. Specifically, in purpose data 212, “within standard range” may be indicated as the optimization purpose of the first product characteristic, and “minimization” may be indicated as the optimization purpose of the second product characteristic. Further, constraint condition data 213 indicates, as the standard range of the first product characteristic, a range from the minimum value “30” to the maximum value “40”, and indicates, as the standard range of the second product characteristic, a range from the minimum value “10” to the maximum value “to”. Therefore, the optimization purpose of the second product characteristic is to minimize the value of the second product characteristic within the standard range of the minimum value “10” or more.

### <Example of Standard Range>

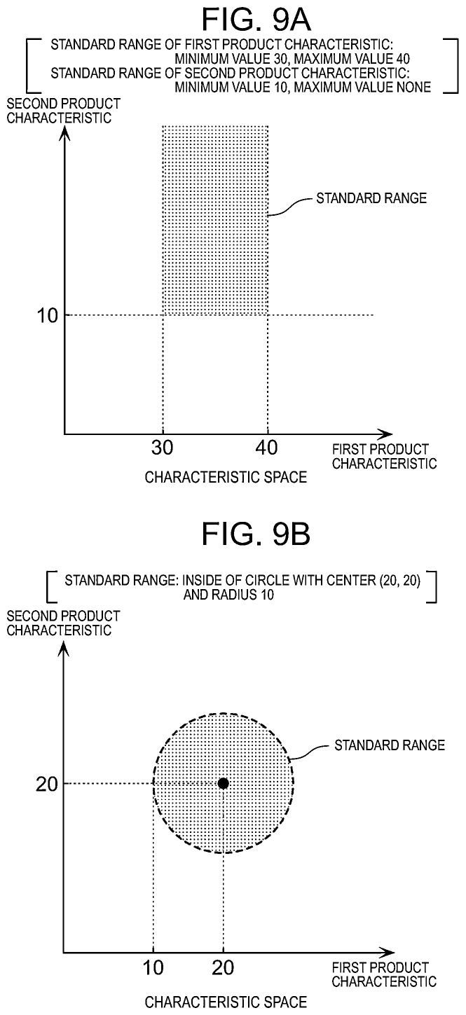

FIG. 9A is a diagram illustrating an example of a standard range.

The standard range indicated by constraint condition data 213 is represented by a rectangular range on the characteristic space, for example, as illustrated in FIG. 9A. In the example illustrated in FIG. 9A, the shape of the standard range is rectangular, but may be another shape. That is, the shape of the standard range may be any shape as long as calculation of an evaluation value to be described later can be implemented.

FIG. 9B is a diagram illustrating another example of the standard range.

As illustrated in FIG. 9B, the standard range may be, for example, a circular shape. In a specific example, the standard range in the characteristic space of the first product characteristic and the second product characteristic is represented by the center (20, 20) and the radius 10 of a circle. Note that the shape of the standard range may be a shape other than a circular shape, and may be an elliptical shape, a star shape, or the like.

As described above, in the present exemplary embodiment, evaluation value calculating unit 12 may calculate the evaluation value of each candidate control point on the basis of the standard range of the shape different from the rectangle. As a result, in the characteristic space, the evaluation value is calculated on the basis of the standard range such as a circle, an ellipse, and a star, so that the application scene can be further expanded without being limited to the case where the shape of the standard range is a rectangle.

### [Processing Operation]

Evaluation device 100 performs processing related to calculation and output of the evaluation value using each piece of data having been input as described above.

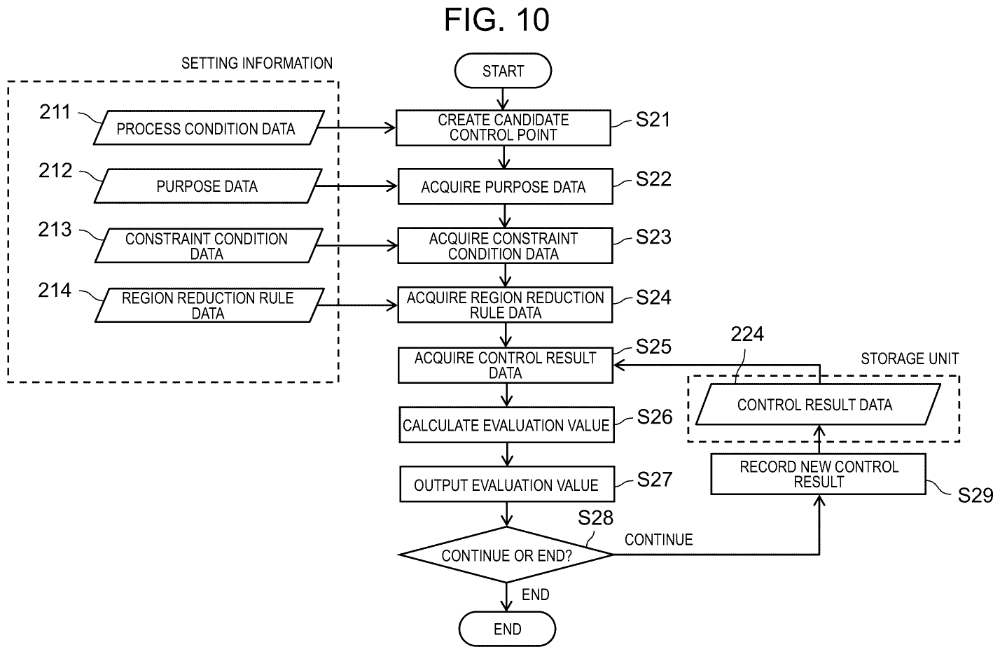

FIG. 10 is a flowchart illustrating a processing operation of evaluation device 100 according to the present exemplary embodiment.

First, candidate control point creating unit 11 generates candidate control point data 221 using process condition data 211 (step S21).

Next, reception controller 10 acquires purpose data 212 (step S22). That is, reception controller 10 executes the second reception step of acquiring purpose data 212 indicating the optimization purpose. Here, the unknown characteristic points indicate values of one or more product characteristics, and at least one product characteristic has an optimization purpose. Further, reception controller 10 acquires constraint condition data 213 (step S23). That is, reception controller 10 executes the third reception step of acquiring constraint condition data 213 indicating the constraint condition applied to at least one product characteristic. Further, reception controller 10 acquires region reduction rule data 214 indicating the rule for calculating the pareto boundary (step S24). That is, reception controller 10 executes the fourth reception step of acquiring region reduction rule data 214 indicating a division method of a characteristic space represented by at least one product characteristic and indicating the dimension for reducing the active region for each region of the characteristic space divided by the division method. Further, reception controller 10 reads control result data 222 from storage unit 105 (step S25). That is, reception controller 10 executes the first reception step of acquiring control result data 222 indicating the controlled control point at the first time and the known characteristic point at the first time. Note that, in a case where none of the characteristic points is indicated in control result data 224, the processing of steps S25 to S27 including step S25 is skipped.

Then, evaluation value calculating unit 12 calculates the evaluation value of each candidate control point on the basis of purpose data 212, constraint condition data 213, region reduction rule data 214, candidate control point data 221, and control result data 222 (step S26). That is, evaluation value calculating unit 12 executes the calculation step of calculating the evaluation value of each of the plurality of unknown characteristic points on the basis of the data. Specifically, evaluation value calculating unit 12 calculates the evaluation value of each candidate control point indicated in candidate control point data 221 using a method for calculating an improvement amount that is changed based on the region reduction rule. In addition, in this calculation step, evaluation value calculating unit 12 may apply a weighting according to the degree of conformity of the constraint condition to the evaluation value for at least one product characteristic. Then, evaluation value calculating unit 12 generates evaluation value data 224 indicating the calculated evaluation value of each candidate control point.

Next, evaluation value output unit 13 outputs the evaluation value calculated in step S5, that is, evaluation value data 224 to display unit 104 (step S27). That is, evaluation value output unit 13 executes an output step of outputting the evaluation value. As a result, evaluation value data 224 is displayed on display unit 104, for example.

Then, reception controller 10 acquires an operation signal from input unit 101a in response to an input operation to input unit 101a by the user. The operation signal indicates the end of the search for the optimal solution or the continuation of the search for the optimal solution. The search for the optimum solution is processing of calculating and outputting the evaluation value of each candidate control point based on the new control result. Reception controller 10 determines whether the operation signal indicates the end or the continuation of the search for the optimal solution (step S28).

When determining that the operation signal indicates the end of the search for the optimum solution (“end” in step S28), reception controller 10 ends all the processing. On the other hand, when determining that the operation signal indicates the continuation of the search for the optimum solution (“continue” in step S28), reception controller 10 writes the candidate control point selected as the next control point in control result data 222 of storage unit 105. In the mass production site (production process), continuation may be selected while production is continued. For example, when the user performs an input operation on input unit 101a, reception controller 10 selects the candidate control point as the next control point from evaluation value data 224. Reception controller 10 writes the candidate control point thus selected in control result data 222. Then, when the characteristic point corresponding to the next control point is obtained by the control, the user inputs characteristic point data 201 indicating the characteristic point to evaluation device 100 by performing an input operation to input unit 101a. Reception controller 10 acquires input characteristic point data 201, and writes the characteristic point indicated by characteristic point data 201 in control result data 222 of storage unit 105. At this time, the characteristic point is associated with the most recently selected and written control point. As a result, a new control result is recorded in control result data 222 (step S29). That is, control result data 222 is updated. When control result data 222 is updated, evaluation value calculating unit 12 repeatedly executes the processing from step S25.

Through the above flow, the optimum control condition (that is, the candidate control point) to be performed next can be quantitatively analyzed from the past control result. As a result, the development cycle can be expected to be shortened regardless of the ability of the analyst such as the user.

### <Example of Candidate Control Point Data 221>

FIG. 11A is a diagram illustrating an example of candidate control point data 221.

Candidate control point creating unit 11 generates candidate control point data 221 illustrated in FIG. 11A based on process condition data 211. For example, in a case where each value of all the process conditions indicated by process condition data 211 is a value of a continuous variable and there is no constraint on the value, candidate control point creating unit 11 creates each of all combinations of values of each process condition as a candidate control point. For example, it is assumed that process condition data 211 indicates a value “10, 20, 30, 40, 50” of the continuous variable of the first process condition and a value “100, 200, 300, 400, 500” of the continuous variable of the second process condition. In this case, candidate control point creating unit 11 creates, as candidate control points, all combinations including a combination of the value “10” of the first process condition and the value “100” of the second process condition and a combination of the value “10” of the first process condition and the value “200” of the second process condition. Candidate control point creating unit 11 associates a control point number with the created candidate control point, and generates candidate control point data 221 indicating the candidate control point with which the control point number is associated.

In a specific example, as shown in FIG. 11A, candidate control point data 221 indicates a candidate control point (10,100) associated with a control point number “1”, a candidate control point (10,200) associated with a control point number “2”, a candidate control point (10,300) associated with a control point number “3”, and the like. A first component of these candidate control points indicates the value of the first process condition, and a second component indicates the value of the second process condition.

Here, among all combinations of values, only a combination of values satisfying a certain constraint may be created as the candidate control point. For example, in the material development, when the first compound and the second compound are set as the first process condition and the second process condition, respectively, and the compounding ratio thereof is set as the value, candidate control point creating unit 11 adopts only a combination of values in which the sum satisfies 1 as the candidate control point. An example is shown in candidate control point data 221 of FIG. 11B.

FIG. 11B is a diagram illustrating another example of candidate control point data 221.

Candidate control point creating unit 11 generates candidate control point data 221 illustrated in FIG. 11B based on process condition data 211. For example, it is assumed that process condition data 211 indicates “0.0, 0.2, 0.4, 0.6, 0.8, 1.0” as the value of the ratio variable of the second process condition, and indicates “0.0, 0.2, 0.4, 0.6, 0.8, 1.0” as the value of the ratio variable of the third process condition. In this case, the combination of the values of these ratio variables corresponds to the compounding ratio of the first compound and the second compound described above. Therefore, candidate control point creating unit 11 may create a combination of the value of the first process condition, the value of the second process condition, and the value of the third process condition as the candidate control point so that the sum of the value of the ratio variable of the second process condition and the value of the ratio variable of the third process condition satisfies 1. For example, candidate control point creating unit 11 may create, as a candidate control point, a combination of values in which the sum of the values of the ratio variables satisfies 1, such as a combination of the value “10” of the first process condition, the value “0.2” of the second process condition, and the value “0.8” of the third process condition. Candidate control point creating unit 11 associates a control point number with the created candidate control point, and generates candidate control point data 221 indicating the candidate control point with which the control point number is associated.

In a specific example, as shown in FIG. 11B, candidate control point data 221 indicates a candidate control point (10, 0.0, 1.0) associated with the control point number “1”, a candidate control point (10, 0.2, 0.8) associated with the control point number “2”, a candidate control point (10, 0.4, 0.6) associated with the control point number “3”, and the like. Note that the first component of these candidate control points indicates the value of the first process condition, the second component indicates the value of the second process condition, and the third component indicates the value of the third process condition.

As described above, in the present exemplary embodiment, in a case where there are a plurality of process conditions, when creating each of the plurality of candidate control points, candidate control point creating unit 11 creates the candidate control point by combining values satisfying a predetermined condition of each of the plurality of process conditions. For example, as illustrated in FIG. 11B, the predetermined condition is a condition that the sum of the values of the ratio variables of the plurality of process conditions is 1. In a more specific example, the ratio variable is a compounding ratio of materials such as compounds corresponding to the process conditions. Therefore, for each combination of compounding ratios of a plurality of kinds of compounds, an evaluation value for the combination can be calculated. As a result, it is possible to appropriately search for an optimal solution for one or more product characteristics of the synthetic material obtained by compounding these compounds.

### <Example of Control Result Data 222>

FIG. 12 is a diagram illustrating an example of control result data 222.

Evaluation value calculating unit 12 reads control result data 222 stored in storage unit 105 in order to calculate the evaluation value. As illustrated in FIG. 12, control result data 222 indicates, for each control number, a control point used in the control identified by the control number and a characteristic point that is a control result obtained by the control. The control point is represented by a combination of values of each process condition. For example, the control point is represented by a combination of values that is a combination of the value “10” of the first process condition and the value “100” of the second process condition. The characteristic point is represented by a combination of values of each product characteristic obtained by the control. Hereinafter, the value of the product characteristic is also referred to as a product characteristic value. For example, the characteristic point is represented by a combination of the value “8” of the first product characteristic and the value “0.0” of the second product characteristic.

In a specific example, control result data 222 indicates the control point (10,100) and the characteristic point (8, 0.0) associated with the control number “1”, the control point (10,500) and the characteristic point (40, 1.6) associated with the control number “2”, the control point (50,100) and the characteristic point (40, 1.6) associated with the control number “3”, and the like, as illustrated in FIG. 12.

### [Evaluation Value Calculation Processing]

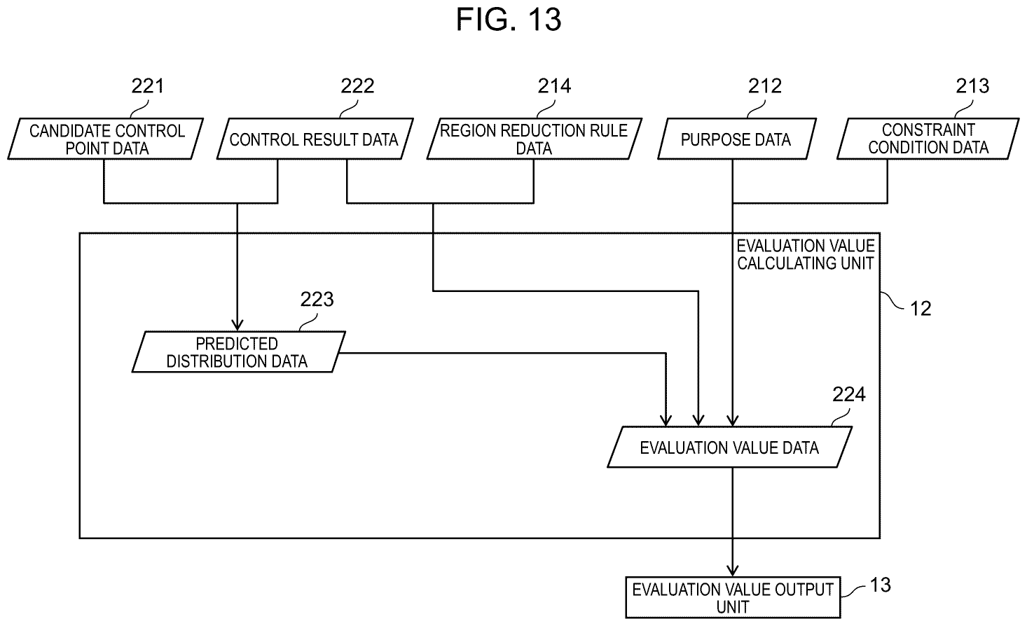

FIG. 13 is a diagram for explaining processing by evaluation value calculating unit 12. Evaluation value calculating unit 12 generates predicted distribution data 223 based on candidate control point data 221 generated by candidate control point creating unit 11 and control result data 222 in storage unit 105. Then, evaluation value calculating unit 12 generates evaluation value data 224 based on purpose data 212 indicating the optimization purpose of each product characteristic, constraint condition data 213 indicating the standard range of each product characteristic, region reduction rule data 214 indicating the rule for calculating the pareto boundary, and predicted distribution data 223.

Here, control result data 222 indicates one or more control points, which are one or more candidate control points already used for control among the plurality of candidate control points, and a characteristic point corresponding to each of the one or more control points, which is a control result of one or more product characteristics using the control point. Therefore, evaluation value calculating unit 12 according to the present exemplary embodiment calculates the evaluation value of each candidate control point on the basis of Bayesian optimization on the basis of (a) the optimization purpose and the standard range of each of one or more product characteristics, (b) one or more control points that are one or more candidate control points already used for control among the plurality of candidate control points, and (c) characteristic points that are characteristic points corresponding to each of the one or more control points and indicate a control result of the one or more product characteristics using the control points.

Evaluation value calculating unit 12 outputs generated evaluation value data 224 to evaluation value output unit 13. Note that evaluation value calculating unit 12 may also output predicted distribution data 223 to evaluation value output unit 13. Alternatively, evaluation value calculating unit 12 may store predicted distribution data 223 in storage unit 105, and evaluation value output unit 13 may read predicted distribution data 223 from storage unit 105 in response to an input operation to input unit 101a by the user.

Evaluation value calculating unit 12 describes the correspondence relationship between the candidate control points and the characteristic points using the Kalman filter described above.

Evaluation value calculating unit 12 generates predicted distribution data 223 by performing calculation using (Equation 3) above on the known control result indicated in control result data 222 read from storage unit 105 in step S25 above.

FIG. 14 is a diagram illustrating an example of predicted distribution data 223. Predicted distribution data 223 indicates the average and variance of the predicted distribution at each candidate control point. This predicted distribution is a distribution calculated by (Equation 3) based on the Kalman filter for each product characteristic. For example, as illustrated in FIG. 14, predicted distribution data 223 indicates, for each control point number, the average and variance of the predicted distribution of the first product characteristic and the average and variance of the predicted distribution of the second product characteristic corresponding to the control point number.

In a specific example, as shown in FIG. 14, predicted distribution data 223 shows an average “23.5322” and a variance “19.4012” of the first product characteristic and an average “0.77661” and a variance “0.97006” of the second product characteristic corresponding to the control point number “1”. Further, predicted distribution data 223 indicates an average “30.2536” and a variance “21.5521” of the first product characteristic and an average “1.11268” and a variance “1.07761” of the second product characteristic corresponding to the control point number “2”. As illustrated in FIG. 11A or 11B, the control point number is associated with the candidate control point.

Evaluation value calculating unit 12 calculates an evaluation value on the basis of an evaluation criterion called an acquisition function in Bayesian optimization. The above-described predicted distribution is used to calculate the evaluation value. In addition, the acquisition function in the present exemplary embodiment is an acquisition function in Bayesian optimization with a constraint condition.

<Acquisition Function of Bayesian Optimization without Constraint Condition>

First, before description of the acquisition function in the present exemplary embodiment, the acquisition function of Bayesian optimization without a constraint condition (that is, EHVI of NPL 1) will be described. However, for the description of the maximization and the minimization, the minimization is used in a unified manner because when one of the maximization and the minimization is inverted in the sign, it becomes equivalent to the other. In the EHVI, it is considered that a characteristic point greatly improved from the provisional control result is obtained as the volume (also referred to as an improvement amount) of the improvement region is larger. The improvement region is a region surrounded by a pareto boundary determined from the coordinates of a pareto point (that is, a non-inferior solution) among at least one characteristic point already obtained from the performed control and a pareto boundary newly determined by a new characteristic point when the new characteristic point is observed. Note that the Pareto point is a characteristic point that is provisionally regarded as a Pareto solution at the present time. For example, when the optimization purpose of each of the first product characteristic and the second product characteristic is minimization, there is no other characteristic point at which both values of the first product characteristic and the second product characteristic are smaller than the pareto point. The pareto boundary is a boundary line determined by connecting the coordinates of the pareto points along the directions of the first product characteristic and the second product characteristic. In the following description, among the entire characteristic space divided by the Pareto boundary, a side with a smaller value for each product characteristic is referred to as an active region, and a side with a larger value is referred to as an inactive region. The amount of improvement when the new characteristic point enters the inactive region is set to 0.

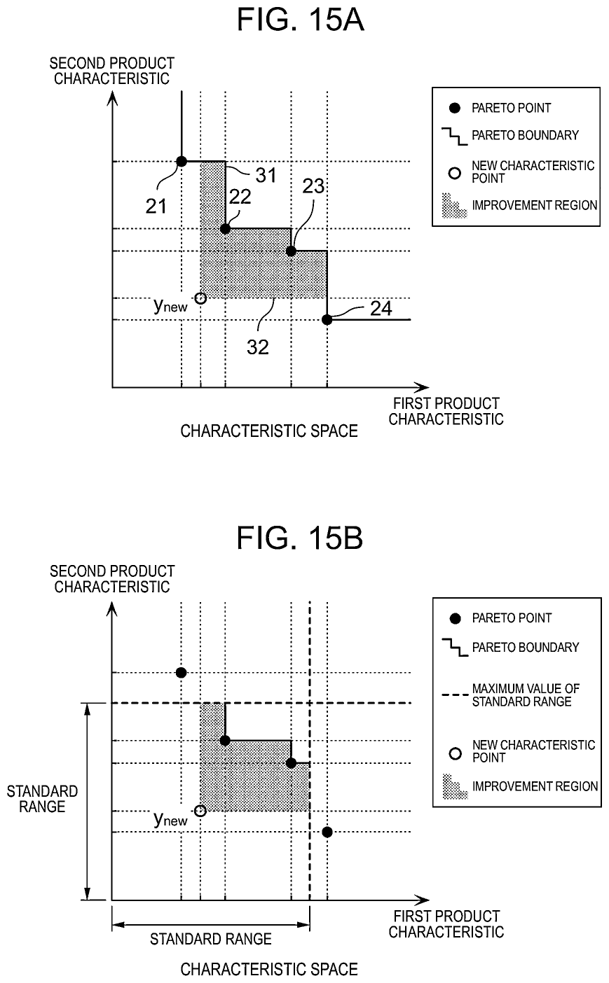

FIG. 15A is a diagram illustrating an example of an improvement region.

For example, as illustrated in FIG. 15A, a region surrounded by a Pareto boundary 31 determined from the four Pareto points 21 to 24 and a Pareto boundary 32 newly determined when one new characteristic point y_{new} is obtained is identified as the improvement region.

Here, the behavior of each product characteristic value when each candidate control point is selected by the Kalman filter is represented in the form of a normal distribution, and the amount of improvement also varies depending on the position of the observed characteristic point. The EHVI is defined as an amount obtained by taking an expected value of the amount of improvement in the predicted distribution for each candidate control point as in the following (Equation 6). A candidate control point having a larger value obtained by the EHVI has a larger expected value of the amount of improvement, and represents a control point to be executed next.

$$\begin{matrix}[ Math . 8 ] & \\ EHVI ( {x}_{new} ) = {\int }_{{ℝ}^{D}} I ( {y}_{new} ) p ( {y}_{new} \vert {x}_{new} ) {dy}_{new} & ( Equation 6 )\end{matrix}$$

In (Equation 6), D represents the number of product characteristics (that is, the number of dimensions), and

[Math. 9]

[symbol]

^{D}

represents a D-dimensional Euclidean space, and I (y_{new}) represents an improvement amount. Furthermore, p (y_{new}|X_{new}) represents a predicted distribution of the characteristic point y_{new} corresponding to the new control point X_{new} when one candidate control point is selected from among at least one candidate control point as the new control point X_{new}. The predicted distribution of each dimension of the characteristic point y_{new}, that is, the average and the variance are obtained by the above (Equation 3).

<Acquisition Function of Bayesian Optimization with Constraint Condition>

Next, an acquisition function in the present exemplary embodiment will be described. The acquisition function in the present exemplary embodiment is an acquisition function of Bayesian optimization in a case where there is a constraint condition. Note that, in a case where there is no constraint condition, evaluation value calculating unit 12 may use the acquisition function represented by the above (Equation 6). It is assumed that among D product characteristics, the optimization purpose of the D_{Dminimize} product characteristics of y₁ to y_{Dminimize} is minimization, and the optimization purpose of the remaining D_{range} (=D−D_{minimize}) product characteristics of y_{Dminimize}+1 to y_{D} is within a standard range. At this time, the acquisition function in the present exemplary embodiment, that is, the constrained EHVIC is defined as the following (Equation 7).

$$\begin{matrix}[ Math . 10 ] & \\ EHVIC ( {x}_{new} ) = {\int }_{{R}_{minimize}} IC ( {y}_{new} ) p ( {y}_{new , minimize} \vert {x}_{new} ) {dy}_{new , minimize} \times Pr \{ {y}_{new , range} ∈ {R}_{range} \} & ( Equation 7 )\end{matrix}$$

In (Equation 7), R_{minimize} represents a region where all the product characteristics y₁ to y_{Dminimize} whose optimization purpose is minimization are within the standard range. R_{range} represents a region within the standard range for all the product characteristics Y_{Dminimize+1} to y_{D} whose optimization purpose is within the standard range. Note that each region of R_{minimize} and R_{range} is represented by a function indicating a shape of a standard range corresponding to the region. As illustrated in FIG. 9B, when the shape of the standard range is a circle, each region of R_{minimize} and R_{range} is represented by a function indicating the circle. In addition, when the shape of the standard range is a star shape, each region of R_{minimize} and R_{range} is represented by a function indicating the star shape. y_{new,minimize} represents a vector obtained by extracting each dimension of the product characteristic whose optimization purpose is minimization from all dimensions of the characteristic point y_{new}. y_{new,range} represents a vector obtained by extracting each dimension of the product characteristic whose optimization purpose is within the standard range from all dimensions of the characteristic point y_{new}. IC (y_{new}) is an amount of improvement in a case where there is a constraint condition, and represents a volume of a region surrounded by an existing Pareto boundary and a newly determined Pareto boundary. The existing Pareto boundary is a boundary determined from at least one Pareto point existing within the standard range and each coordinate in the standard range. The newly determined pareto boundary is a boundary determined from the respective coordinates of the pareto point and the standard range that are new characteristic points when the new characteristic point is observed. Pᵣ{A} represents a probability that the event A is established, and is represented using, for example, an average and a variance calculated by (Equation 3).

FIG. 15B is a diagram illustrating another example of the improvement region according to the present exemplary embodiment. A major difference between the present exemplary embodiment and NPL 2 is that, regarding the product characteristic whose optimization purpose is minimization, in the present exemplary embodiment, an integration range is limited within a standard range from the entire characteristic space, and the way of measuring the improvement amount changes according to the standard range. When the maximum value and the minimum value in the standard range are not designated, the maximum value is set as +∞, and the minimum value is set as −∞. When the maximum value and the minimum value in the standard range of all the product characteristics whose optimization purpose is the minimization are +∞ and −∞, respectively, and D_{range}=0, EHVIC, which is the acquisition function in the present exemplary embodiment, results in EHVI of NPL 1. In addition, when the maximum value and the minimum value in the standard range of all the product characteristics whose optimization purpose is minimization are +∞ and −∞, respectively, and D_{range}>=1, EHVIC, which is the acquisition function in the present exemplary embodiment, results in EHVIC of NPL 2. Therefore, evaluation device 100 according to the present exemplary embodiment can also calculate the evaluation value by the conventional method.

In addition, NPL 2 assumes an optimization problem in which there are one or more product characteristics whose optimization purpose is minimization, that is, D_{minimize}>=1, but in the acquisition function in the present exemplary embodiment, formulation can be performed without any inconvenience even in a case of D_{minimize}=0 (that is, D_{range}=D). Therefore, the acquisition function in the present exemplary embodiment is naturally extended also to the optimization problem in which the optimization purpose of all the product characteristics is within the standard range.

Next, a specific calculation method of the EHVIC that is the acquisition function in the present exemplary embodiment will be described.

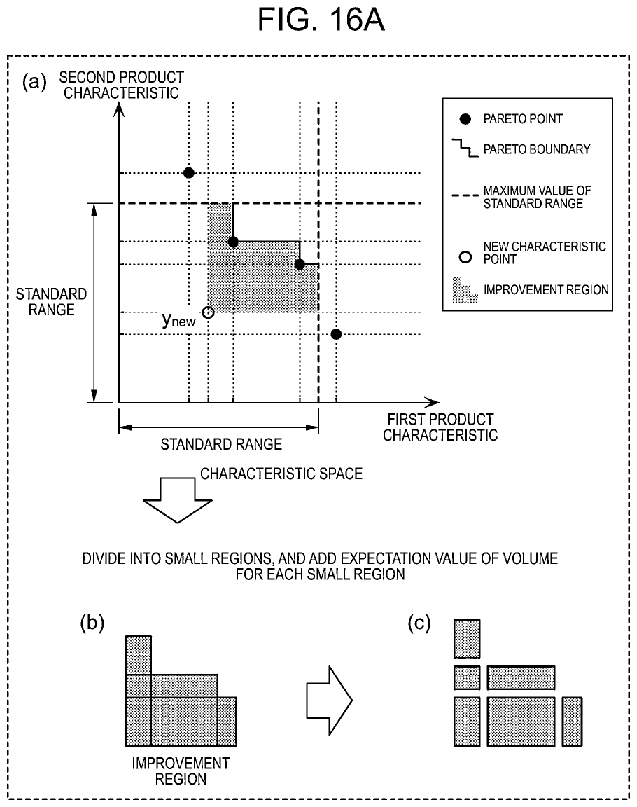

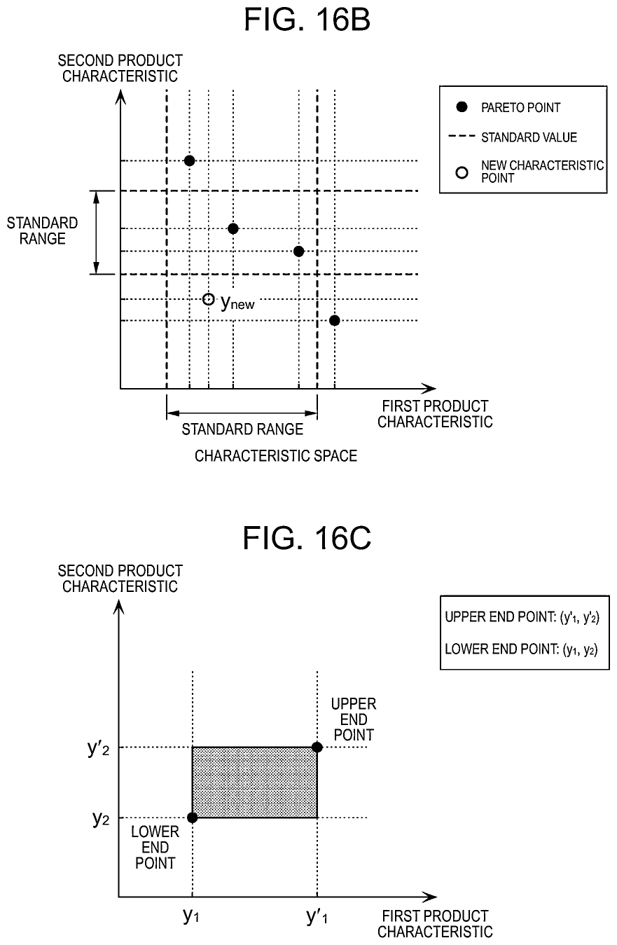

FIG. 16A is a diagram for explaining a method of calculating the volume of the improvement region. Note that part (a) of FIG. 16A illustrates an improvement region in the characteristic space, part (b) of FIG. 16A illustrates the improvement region to be divided, and part (c) of FIG. 16A illustrates a plurality of small regions obtained by dividing the improvement region.

Evaluation value calculating unit 12 calculates the improvement amount (that is, IC (y_{new})), which is the volume of the improvement region, as illustrated in FIG. 16A with respect to the dimension of the product characteristic whose optimization purpose is minimization. That is, evaluation value calculating unit 12 divides the improvement region into a plurality of small regions at the coordinates of each of the pareto point and the new characteristic point, calculates the expected value of the volume of each small region, and then calculates the improvement amount (that is, IC (y_{new})) by calculating the sum of the expected values. Evaluation value calculating unit 12 calculates the probability that each product characteristic value falls within the standard range for the dimension of the product characteristic whose optimization purpose is within the standard range.

FIG. 16B is a diagram illustrating an example in which the entire characteristic space is divided into a plurality of small regions.

Evaluation value calculating unit 12 divides the entire characteristic space into a plurality of small regions as illustrated in FIG. 16B with respect to the dimension of the product characteristic of which the optimization purpose is minimized and the dimension of the product characteristic of which the optimization purpose is within the standard range, and uniformly calculates the acquisition function by using the following (Formula 8). That is, evaluation value calculating unit 12 divides the entire characteristic space into a plurality of small regions at the coordinates of each of the pareto point, the new characteristic point, and the standard value, and executes calculation of the volume of each small region by case-by-case calculation as in (Equation 8) below. The standard values described above are the maximum value and the minimum value in the standard range. Then, by calculating the sum of the volumes of those small regions subjected to expectation value processing, evaluation value calculating unit 12 uniformly calculates the acquisition function in a case where there is a constraint condition. The volume is also referred to as a D-dimensional hypervolume.

$$\begin{matrix}[ Math . 11 ] & \\ ( Volume of small region ) = {\prod }_{d = 1}^{D} {c}_{d} \times l ( {y}_{d} , {{y}^{′}}_{d} ) & ( Equation 8 )\end{matrix}$$

$$l ( {y}_{d} , {{y}_{d}}^{′} ) = \{ \begin{matrix}0 & ( i ) \\ 1 & ( ii ) \\ ( {{y}^{′}}_{d} - {y}_{d} ) & ( iii )\end{matrix}$$

In (Equation 8), y_{d} represents the d-th component of the lower end point (y₁, . . . , y_{D}) of the small region, and y′_{d} represents the d-th component of the upper end point (y′₁, . . . , y′_{D}) of the small region.

FIG. 16C is a diagram illustrating an example of a lower end point and an upper end point of the small region.

In the case of D=2, as illustrated in FIG. 16C, (y₁, y₂) represents the lower end point of the small region, and (y′₁, y′₂) represents the upper end point of the small region.

(i) in (Equation 8) is applied when the interval [y_{d}, y′_{d}] is out of the standard range with respect to the dimension d. (ii) is applied when the interval [y_{d}, y′_{d}] is within the standard range with respect to the dimension d and the optimization purpose of the product characteristics of the dimension d is within the standard range. (iii) is applied when the interval [y_{d}, y′_{d}] is within the standard range with respect to the dimension d and the optimization purpose of the product properties of the dimension d is minimization. c_{d} is a weighting coefficient, and is appropriately set, for example, when a search priority is given for each dimension d of the product characteristic. For example, as the priority of the dimension d is higher, a smaller weighting coefficient c_{d} is used, and conversely, as the priority of the dimension d is lower, a larger weighting coefficient c_{d} is used. The reciprocal of weighting coefficient c_{d} may be the priority. Unless otherwise specified, that is, when the priority of each dimension d is equal, c_{d} of each dimension d is set to 1, for example.

The above is the description of the acquisition function and the specific calculation method of the acquisition function in the present exemplary embodiment.

This enables quantitative evaluation with a consistent procedure even in a multi-purpose optimization problem with a constraint condition. More specifically, the volume within the constraint range in the characteristic space is calculated as the optimization improvement amount for each candidate control point using the acquisition function of the Bayesian optimization in a case where there is a constraint condition, and the evaluation value can be appropriately calculated from the improvement amount.

However, when the acquisition function of the Bayesian optimization in a case where there is a constraint condition is calculated, for example, it is necessary to divide the improvement region into a plurality of small regions as illustrated in FIG. 16A, calculate the expected value of the volume of each small region, and then take the sum of the expected values. More generally, when the number of product characteristics, that is, the number of dimensions is D, the improvement region can be represented by a sum region of a plurality of D-dimensional hyper-cuboids. For this reason, when the acquisition function of the Bayesian optimization in a case where there is a constraint condition is calculated, it is necessary to calculate by dividing the improvement region into a plurality of D-dimensional hyper-cuboids, calculating an expected value of the volume of each hyper-cuboid, and then taking the sum of the expected values. Therefore, the calculation amount of the acquisition function greatly depends on the number of hyper-cuboids constituting the improvement region. The number of hyper-cuboids is calculated by using D, which is the number of product characteristics (number of dimensions), and Nₚₐᵣₑₜₒ, which is the number of pareto points among the observed characteristic points.

[Math. 12]

O(N^{D}^{²}ₚₐᵣₑₜₒ)

It increases exponentially on the order of magnitude. In practical use, mostly 3-dimension (D=3) is a calculation limit.

Therefore, in the following, a method for calculating the volume of the improvement region, which has been improved for reducing the calculation amount while maintaining the search efficiency and for executing quantitative evaluation at high speed, will be described.

### <Improved Method for Calculating Volume of Improvement Region>

Before describing an improved method for calculating the volume of the improvement region, a region reduction rule that indicates a rule of calculating a pareto boundary and changes a method for calculating an improvement amount will be described.

The region reduction rule indicates a method for dividing the characteristic space into a predetermined number of regions and a method for calculating a pareto boundary. In the following description, it is assumed that a standard range is not set in order to simplify the description.

When the region reduction rule is applied, the entire characteristic space is divided (region division) into D+1 regions for the number D of product characteristics, that is, D-dimensional product characteristics. The region division method may be any method. The regions of the characteristic space divided into the regions are sequentially named as region 1, region 2, . . . , region D, and region D+1.

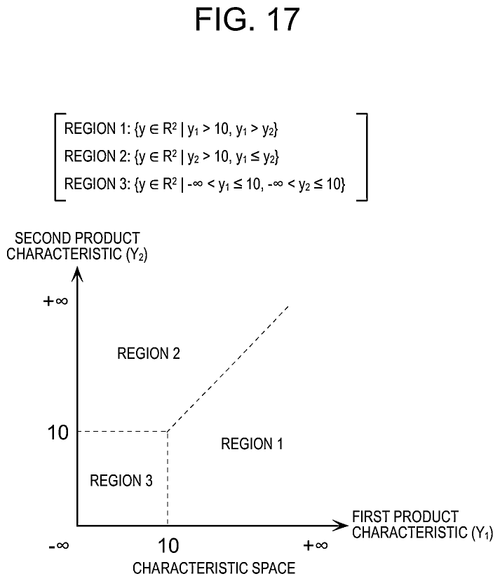

FIG. 17 is a diagram illustrating an example of a characteristic space divided into regions in a case where the region reduction rule is applied. In the example illustrated in FIG. 17, since the number of product characteristics is two (D=2), the characteristic space is divided into three regions, that is, region 1, region 2, and region 3.

In the example illustrated in FIG. 17, a third region including a range of first product characteristics of “−00” to “10” and a range of second product characteristics of “−∞” to “10” in the characteristic space is illustrated. In addition, in the characteristic space, a first region that is a region excluding the third region and below a straight line defined by an inclination of 45 degrees and a second region that is a region excluding the third region and above the straight line defined by an inclination of 45 degrees are illustrated.

Note that, in a case where the region reduction rule is applied, an empty set may be set in the D+1 regions of the region-divided characteristic space, but since it is nonsense that all the D+1 regions are empty sets, at least one of the D+1 regions is set as a set that is not empty.

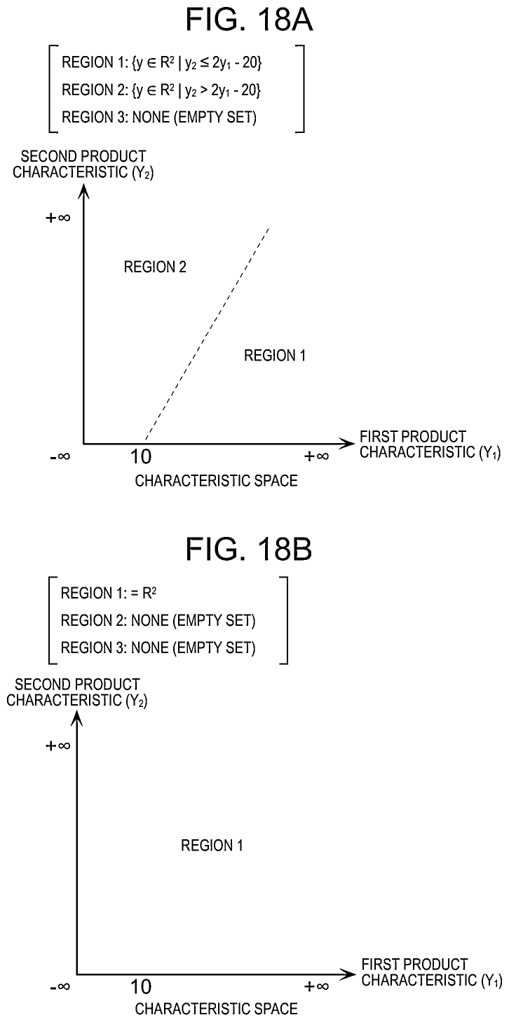

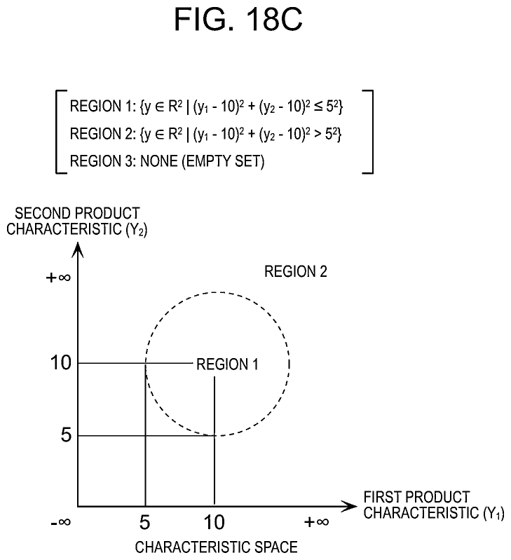

FIGS. 18A to 18C are diagrams illustrating another example of the characteristic space region-divided in a case where the region reduction rule according to the present exemplary embodiment is applied.

The example illustrated in FIG. 18A illustrates a case where the characteristic space is divided into two regions by setting the region 3 to an empty set for the two-dimensional product characteristic. More specifically, as illustrated in FIG. 18A, since the third region is an empty set, the characteristic space is divided into the first region that is a region below the straight line defined by an inclination of 45 degrees and the second region that is a region above the straight line defined by an inclination of 45 degrees.

In the example illustrated in FIG. 18B, a case where since the second region and the third region are set to empty sets for the two-dimensional product characteristic, the characteristic space is divided into one region 1 is illustrated. More specifically, as illustrated in FIG. 18B, since the second region and the third region are empty sets, the entire characteristic space is region-divided into only the first region.

The example illustrated in FIG. 18C illustrates a case where since the region 3 is set to an empty set for the two-dimensional product characteristic, the characteristic space is divided into two regions. That is, in the example illustrated in FIG. 18C, since the third region is an empty set, the entire characteristic space is region-divided into the first region and the second region. More specifically, as illustrated in FIG. 18C, the characteristic space is region-divided into the first region that is a region represented by the center (10,10) of the circle and the radius of 5, and the second region that is a region other than the first region in the characteristic space.

In this way, when the region reduction rule is applied, an empty set may be set in the D+1 regions of the region-divided characteristic space. However, in this case, an arbitrary point on the characteristic space is allocated to any one region other than the empty set.

Next, a method for calculating a pareto boundary in a case where the region reduction rule is applied will be described.

Here, as described above, the Pareto point is a characteristic point that is temporarily regarded as a Pareto solution at the present time, and is also referred to as a non-inferior solution. For example, in a characteristic space constituted by two-dimensional product characteristic, it is assumed that the optimization purpose of each of the first product characteristic and the second product characteristic is minimization. In this case, the pareto point is a characteristic point at which there is no other characteristic point having a smaller value of both the first product characteristic and the second product characteristic than all the other characteristic points observed.

The pareto boundary is a boundary determined from the coordinates of at least one pareto point. For example, as illustrated in FIG. 16A, the above-described Pareto boundary is a boundary line determined by extending and connecting the coordinates of the Pareto points in a direction in which the values of the first product characteristic and the second product characteristic are large. On the other hand, when the region reduction rule is applied, the method for calculating the pareto boundary is changed. That is, when the region reduction rule is applied, the definition of the pareto boundary is changed by determining the dimension in which the active region is reduced for each region.

Here, a method for calculating a pareto boundary in a case where the definition of the pareto boundary is changed by applying the region reduction rule will be described.

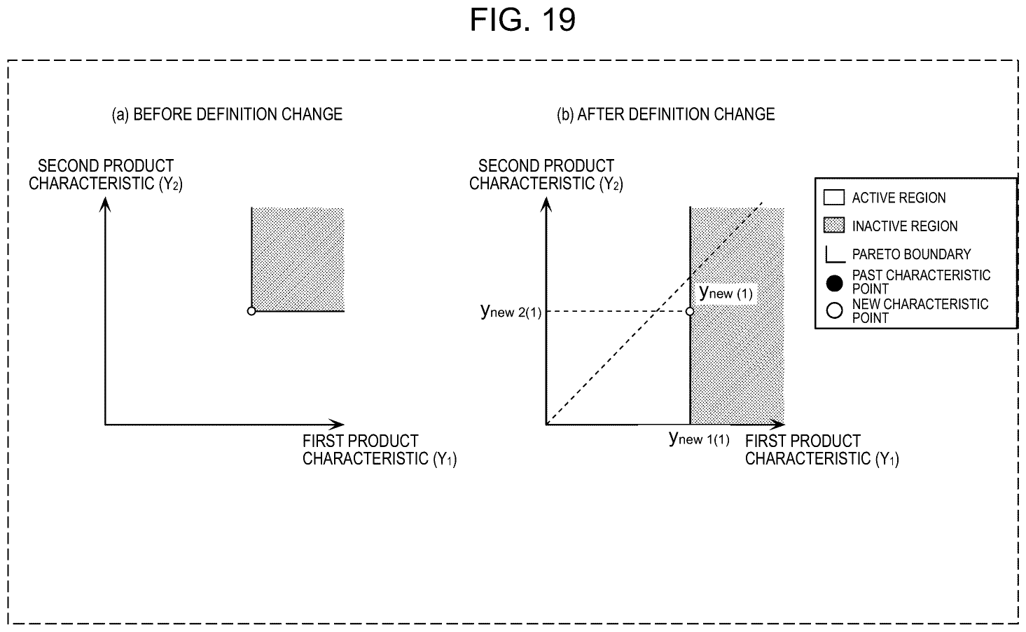

FIGS. 19 to 22 are diagrams for explaining a method for calculating a pareto boundary to which the region reduction rule is applied. Parts (a) of FIGS. 19 to 22 illustrate an example of a method for calculating a pareto boundary before the definition change, that is, a method for calculating a pareto boundary to which the region reduction rule is not applied. Parts (b) of FIGS. 19 to 22 illustrate an example of a method for calculating a pareto boundary before the definition change, that is, a method for calculating a pareto boundary to which the region reduction rule is not applied. In FIGS. 19 to 22, for example, in a characteristic space constituted by two-dimensional product characteristic, it is assumed that the optimization purpose of each of the first product characteristic and the second product characteristic is minimization. In addition, in parts (b) of FIGS. 19 to 22, it is assumed that the characteristic space is region-divided into a region 1 and a region 2 by a straight line passing through the origin and defined by an inclination of 45 degrees.

For example, in FIG. 19, when the first new characteristic point y_{new(1)} is obtained, the new characteristic point y_{new(1)} is the Pareto point. In this case, as illustrated in part (a) of FIG. 19, when the region reduction rule is not applied and the definition is not changed, the boundary line determined by connecting the coordinates of the new characteristic points y_{new(1)} along the directions of the first product characteristic and the second product characteristic is the pareto boundary. On the other hand, as illustrated in part (b) of FIG. 19, when the region reduction rule is applied and the definition is changed, since the new characteristic point y_{new(1)} is located in the region 2, the boundary line that passes through the coordinates of the first product characteristic of the new characteristic point y_{new(1)} and is determined by being parallel to the axis of the second product characteristic becomes the Pareto boundary. In other words, the coordinate y_{new1(1)} of the first product characteristic of the new characteristic point y_{new(1)} is greater than the coordinate y_{new2(1)} of the second product characteristic of the new characteristic point y_{new(1)}. Therefore, the region on the right side of the new characteristic point y_{new1(1)} is set as the inactive region. Furthermore, this can also be represented as reducing (reducing) the active region at the coordinate y_{new1(1)} of the new characteristic point y_{new(1)}.

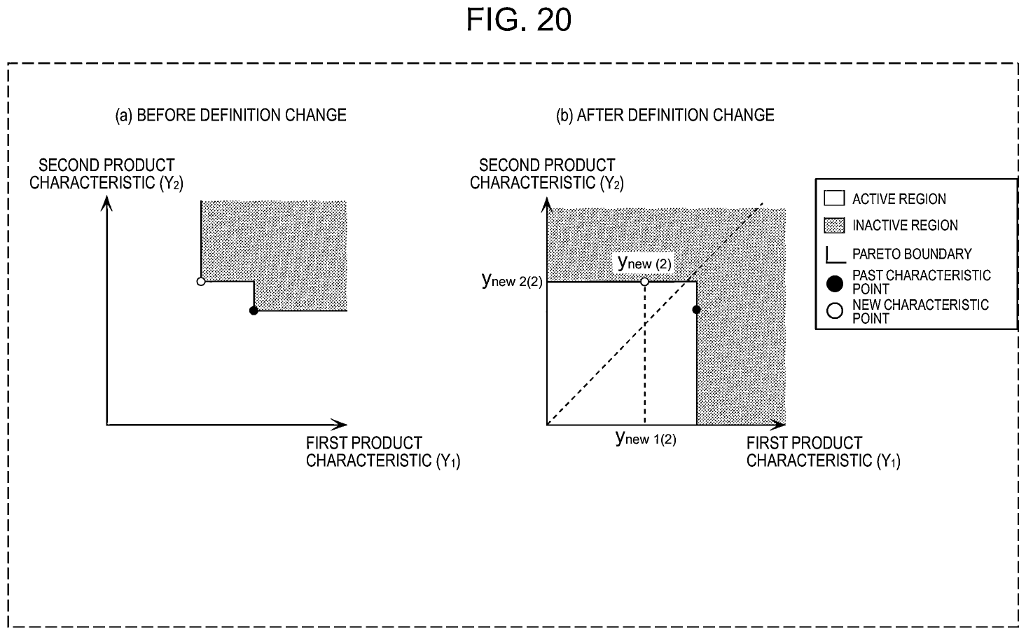

Next, for example, in FIG. 20, when the second new characteristic point y_{new(2)} is obtained, the new characteristic point y_{new(2)} is a pareto point. In this case, as illustrated in part (a) of FIG. 20, when the region reduction rule is not applied and the definition is not changed, a boundary line determined by extending and connecting the coordinates of the characteristic point y_{new(1)} and the coordinates of the new characteristic point y_{new(2)} in a direction in which the values of the first product characteristic and the second product characteristic are large is the pareto boundary. On the other hand, as illustrated in part (b) of FIG. 20, when the region reduction rule is applied and the definition is changed, the new characteristic point y_{new(2)} is located in the region 1. Therefore, a boundary line including a line that passes through the coordinates of the second product characteristic of the new characteristic point y_{new(2)} and is determined by being parallel to the axis of the first product characteristic and a line that passes through the coordinates of the first product characteristic of the characteristic point y_{new(1)} and is determined by being parallel to the axis of the second product characteristic is a pareto boundary. In other words, the coordinate y_{new2(2)} of the second product characteristic of the new characteristic point y_{new(2)} is greater than the coordinate y_{new1(2)} of the first product characteristic of the new characteristic point y_{new(2)}. Therefore, a region on the right side of the new characteristic point y_{new1(1)} or a region on the upper side of the new characteristic point y_{new2(2)} is set as the inactive region. Furthermore, this can also be represented as further reducing (reducing) the active region at the coordinate y_{new2(2)} of the new characteristic point y_{new(2)}.

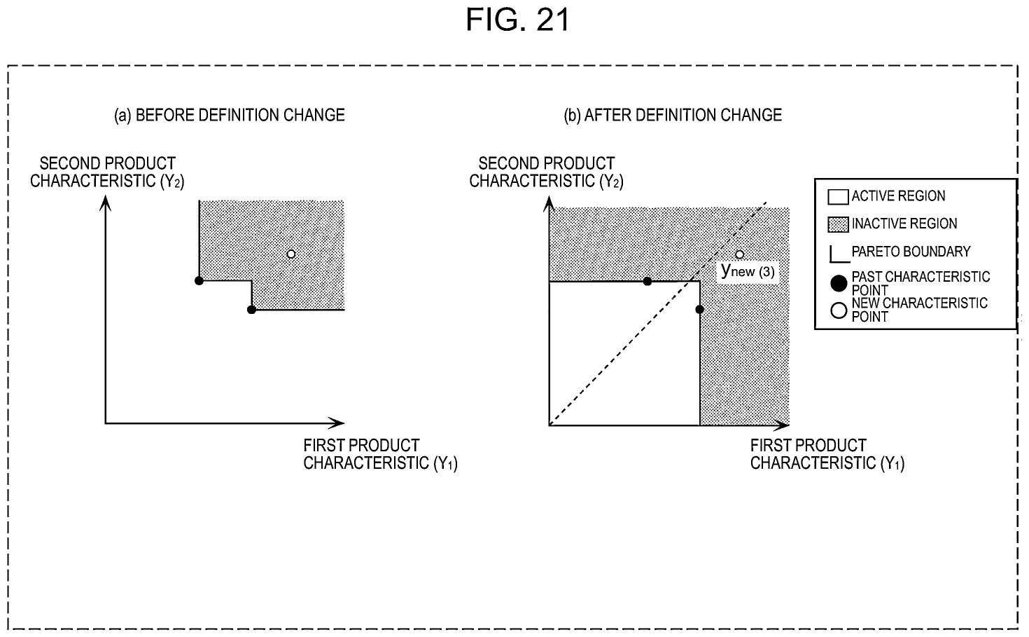

Note that, for example, in FIG. 21, when a third new characteristic point y_{new(3)} is obtained, the new characteristic point y_{new(3)} is not a pareto point. In this case, as illustrated in parts (a) and (b) of FIG. 21, the pareto boundary is not changed. In other words, in a case where the new characteristic point y_{new(3)} is not included in the active region and is included in the inactive region, the new characteristic point y_{new(3)} does not become the pareto point, and thus the pareto boundary is not changed.

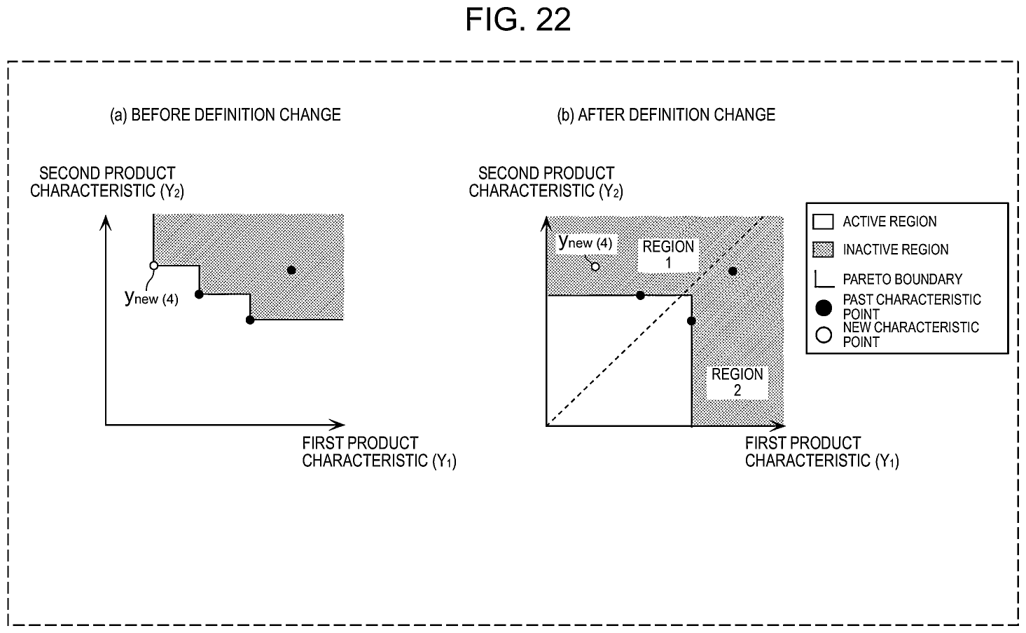

Next, for example, in part (a) of FIG. 22, when a fourth new characteristic point y_{new(4)} is obtained, the new characteristic point y_{new(4)} is a pareto point. In this case, in part (a) of FIG. 22, since the new characteristic point y_{new(4)} is included in the active region, the pareto boundary is changed. On the other hand, in part (b) of FIG. 22, since the new characteristic point y_{new(4)} is included in the inactive region, the pareto boundary is not changed.

As described above, when the region reduction rule is applied, since the dimension in which the active region is reduced is determined for each region, the definition of the pareto boundary is changed.

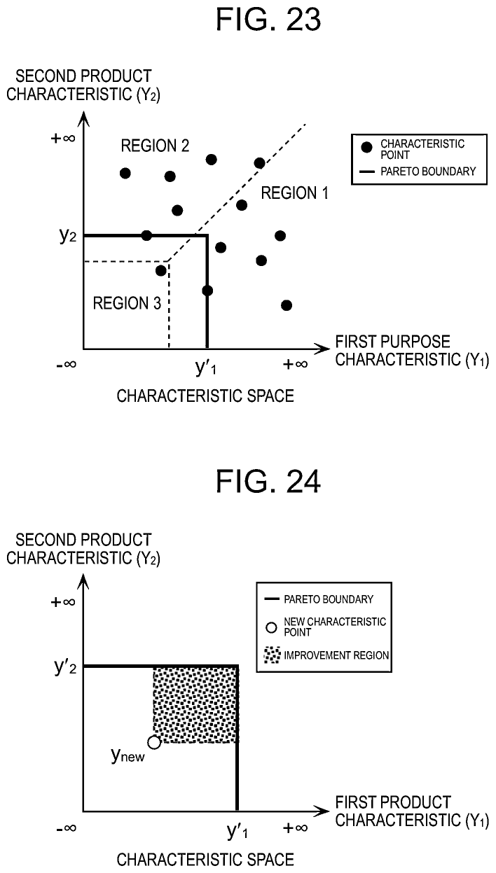

FIG. 23 is a diagram illustrating an example of a pareto boundary in a case where there is no constraint condition. FIG. 23 illustrates an example of the pareto boundary calculated in a case where the region division is performed as illustrated in FIG. 17. In FIG. 23, for example, it is assumed that the optimization purpose of each of the first product characteristic and the second product characteristic is minimization in a characteristic space constituted by two-dimensional product characteristic. Furthermore, in the example illustrated in FIG. 23, the region 1 and the region 2 are used for calculating the Pareto boundary, while the region 3 is not used for calculating the Pareto boundary.

Such a Pareto boundary can be formulated as in (Equation 9).

$$\begin{matrix}[ Math . 13 ] & \\ \{ y ∈ {ℝ}^{D} {\vert}^{∀} d ∈ \{ 1 , … , D \} \vert {y}_{d} \leq {{y}^{′}}_{d} \} \backslash \{ y ∈ {ℝ}^{D} {\vert}^{∀} d ∈ \{ 1 , … , D \} \vert {y}_{d} < {{y}^{′}}_{d} \} & ( Equation 9 )\end{matrix}$$

Here, with respect to the D-dimensional product characteristic, the entire characteristic space is divided into D+1 regions, and for each d=1, . . . . D, a coordinate having the smallest y_{d} coordinate among the characteristic points included in the region d among the observed characteristic points is set as y′_{d}. Note that nothing is performed on the characteristic points included in the region D+1. Furthermore, the initial value of y′_{d} is set as each standard upper limit value. At this time, the region represented by (Equation 9) is the pareto boundary in a case where the region reduction rule is applied. In (Equation 9), D represents the number of product characteristics (number of dimensions), and

[Math. 14]

y∈ [symbol] ^{D}

represents that y is an element of a D-dimensional Euclidean space. \ represents a set (difference set) obtained by removing an element included in the right set of backslash from the left set of backslash.

[Math. 15]

∀

That is, turn A represents taking an “arbitrary” element in the set.

Therefore, evaluation value calculating unit 12 calculates, as the pareto boundary, a boundary determined by the coordinate y′_{d} at the characteristic point having the coordinate y′_{d} having the smallest y_{d} coordinate among the characteristic points included in the region d by (Equation 9).

FIG. 24 is a diagram illustrating an example of an improvement region under the Pareto boundary illustrated in FIG. 23.

As described above, evaluation value calculating unit 12 can calculate the improvement amount (that is, I (y_{new})), which is the volume of the improvement region, as illustrated in FIG. 24, for the dimension of the product characteristic whose optimization purpose is minimization and the dimension of the product characteristic whose optimization purpose is within the standard range. That is, when the region reduction rule is applied, evaluation value calculating unit 12 can calculate the improvement amount (that is, I (y_{new})) by calculating the expected value of the volume of one small region determined by the existing Pareto boundary and the newly determined Pareto point. To explain this intuitively, evaluation value calculating unit 12 can calculate the improvement amount from the amount of increase in the inactive region that can be represented by the expected value of the volume of one small region.

When the y_{d} coordinate of the new characteristic point y_{new} is y_{new,d,} the method of calculating such an improvement amount can be defined as (Equation 10) as the volume of the improvement region (referred to as the improvement amount) when y_{new} is observed.

$$\begin{matrix}[ Math . 16 ] & \\ I ( {y}_{new} ) = {\prod }_{d = 1}^{D} max \{ {y}_{d}^{′} - {y}_{new , d} , 0 \} & ( Equation 10 )\end{matrix}$$

In (Equation 10), y_{new,d} represents the coordinates (d-th component) of the dimension d of the new characteristic point, and y′_{d} represents the coordinates (d-th component) of the dimension d of the observed characteristic point (Pareto point) that defines the Pareto boundary. Furthermore, in (Equation 10), if y_{new,d} is less than y′_{d} with respect to a certain dimension d, the improvement amount (that is, I(y_{new})) becomes a non-negative real number, whereas if y_{new,d} is y′_{d} or more with respect to a certain dimension d, the improvement amount (that is, I(y_{new})) becomes 0 instead of a negative real number.

Then, as the improvement amount (that is, I(y_{new})) represented by the volume of the improvement amount calculated in this manner is larger, it can be considered that a characteristic point greatly improved from the provisional experimental result has been obtained.

In addition, in the present exemplary embodiment, the acquisition function (that is, the constrained EHVIC) in a case where the region reduction rule is applied is defined using the predicted distribution calculated on the basis of the Kalman filter for each candidate control point, similarly to the EHVI. More specifically, the acquisition function in a case where the region reduction rule is applied can be defined by an amount obtained by taking an expected value of an improvement amount as in (Equation 7). Then, whether the control point to be executed next is good or bad is evaluated by the magnitude of the value of the amount obtained by taking the expected value of the improvement amount.

As described above, according to the method for calculating an acquisition function in a case where the region reduction rule is applied, it is possible to calculate the acquisition function as long as an expected value of a volume of a single D-dimensional hyper-cuboids is calculated without requiring division into small regions and sum calculation as in a case where the region reduction rule is not applied. As a result, the calculation amount of the acquisition function in a case where the region reduction rule is applied is independent of the number of pareto points Nₚₐᵣₑₜₒ and can be suppressed to an increase in polynomial order with respect to an increase in the number of product characteristics D, so that high-speed analysis processing can be realized while maintaining search efficiency.

Note that, in the above description, the region reduction rule applied in a case where the standard range is not set has been described, but the present invention is not limited thereto. The standard range may be set, and the region reduction rule is similarly applied.

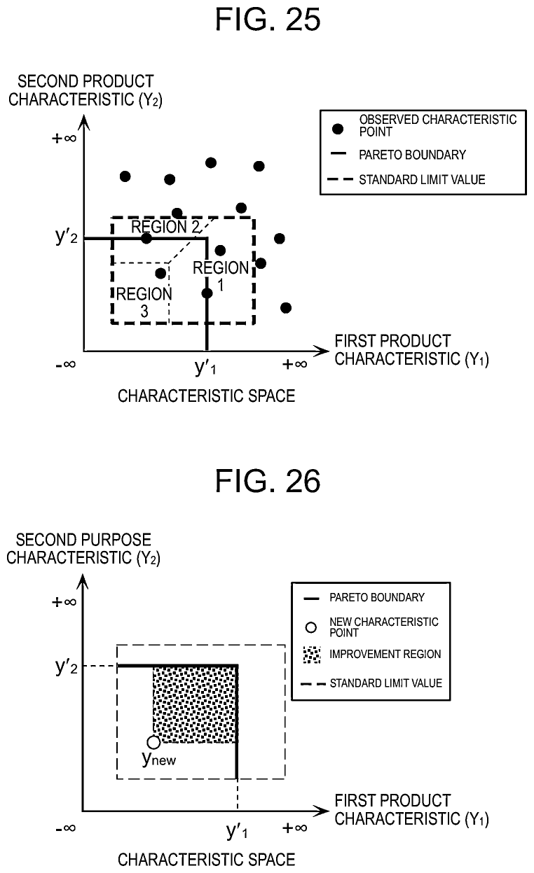

FIG. 25 is a diagram illustrating an example of a pareto boundary in a case where there is a constraint condition. FIG. 26 is a diagram illustrating an example of an improvement region defined in a case where there is a constraint condition under the Pareto boundary illustrated in FIG. 25.

FIG. 26 is different from FIG. 23 in that the standard range is set, and the others are the same. That is, FIG. 25 illustrates an example of a pareto boundary calculated when a standard range is set in a characteristic space region-divided as illustrated in FIG. 17 and constituted by two-dimensional product characteristic. Also in the example illustrated in FIG. 25, it is assumed that the optimization purpose of each of the first product characteristic and the second product characteristic is minimization.

Even in such a case, since the region reduction rule is defined within the standard range, the active region is reduced in the same procedure as described above every time a new characteristic point is observed. That is, evaluation value calculating unit 12 calculates, as an active boundary, a boundary defined by the coordinate y′_{d} of the characteristic point having the smallest y_{d} coordinate among the characteristic points included in the region d and within the standard range by (Equation 9).

Then, since the improvement region is determined as illustrated in FIG. 26, evaluation value calculating unit 12 can calculate the evaluation of the acquisition function using (Equation 7) and (Equation 8).

The above method for calculating an acquisition function is a method for obtaining an exact solution, and can be calculated by the above method as long as a predicted distribution can be calculated by a normal distribution using a Kalman filter or the like, and the acquisition function can be calculated analytically like a rectangle having a single improvement region. However, when the predicted distribution is not a normal distribution or the improvement region has a complicated shape, there is a possibility that the acquisition function cannot be analytically calculated. In such a case, the acquisition function may be approximately calculated using a Monte Carlo method or the like. Even in that case, the division of the characteristic space into small regions, the improvement region, and the like are the same as those described above.

Note that, in the above description, the case where the standard range is provided as the constraint condition has also been described, but the present invention is not limited thereto. Not only the standard range but also a range other than the standard range may be provided. For example, a case where a management range in which the characteristic point is desired to be contained as much as possible is set in a standard range in which the characteristic point is desired to be contained at the minimum is also often required in practice. Note that each of the standard range and the management range is an example of a constraint range that is a constraint condition.

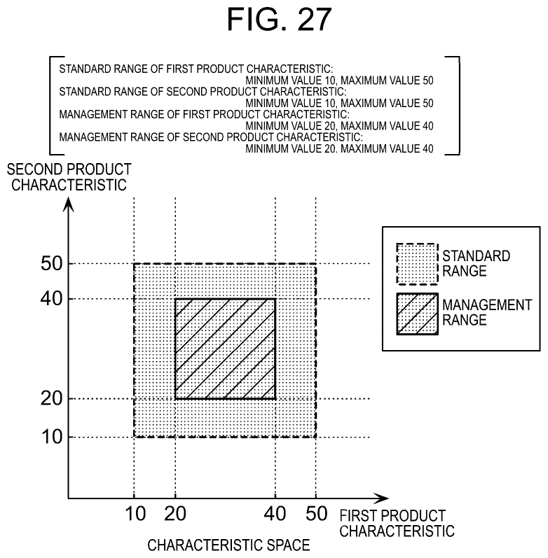

FIG. 27 is a diagram illustrating an example of a standard range and a management range.

In the example shown in FIG. 27, the standard range of the first product characteristic is a minimum value “10” to a maximum value “50”, and the standard range of the second product characteristic is a minimum value “10” to a maximum value “50”. The management range of the first product characteristic is a range narrower than the standard range, that is, a minimum value “20” to a maximum value “40”, and the management range of the second product characteristic is a range narrower than the standard range, that is, a minimum value “20” to a maximum value “40”. In this way, the management range may be included in the standard range.

In such a case, evaluation value calculating unit 12 can calculate the evaluation value by further setting an intermediate value between 0 and 1, for example, 0.5 in (Equation 8), for l(y_{d}, y_{d}′). Note that 0.5 is an example, and may be another numerical value.

### [Output]

Evaluation value output unit 13 acquires evaluation value data 224 indicating the evaluation value of each candidate control point calculated as described above by evaluation value calculating unit 12, and causes display unit 104 to display evaluation value data 224. Note that evaluation value output unit 13 may directly acquire evaluation value data 224 from evaluation value calculating unit 12, or may acquire evaluation value data 224 by reading evaluation value data 224 stored in storage unit 105 by evaluation value calculating unit 12.

FIG. 28 is a diagram illustrating an example of evaluation value data 224. For example, as illustrated in FIG. 28, evaluation value data 224 indicates an evaluation value and a rank of the evaluation value at each candidate control point. Specifically, evaluation value data 224 indicates, for each control point number, an evaluation value corresponding to the control point number and a rank of the evaluation value. As illustrated in FIGS. 11A and 11B, each control point number is associated with a candidate control point. Therefore, it can be said that evaluation value data 224 indicates, for each candidate control point, the evaluation value corresponding to the candidate control point and the rank of the evaluation value. In addition, the rank indicates a smaller numerical value as the evaluation value is larger, and conversely, the rank indicates a larger numerical value as the evaluation value is smaller.

In a specific example, as illustrated in FIG. 28, evaluation value data 224 indicates an evaluation value “0.00000” and a rank “23” corresponding to the control point number “1”, an evaluation value “0.87682” and a rank “1” corresponding to the control point number “2”, an evaluation value “0.62342” and a rank “4” corresponding to the control point number “3”, and the like.

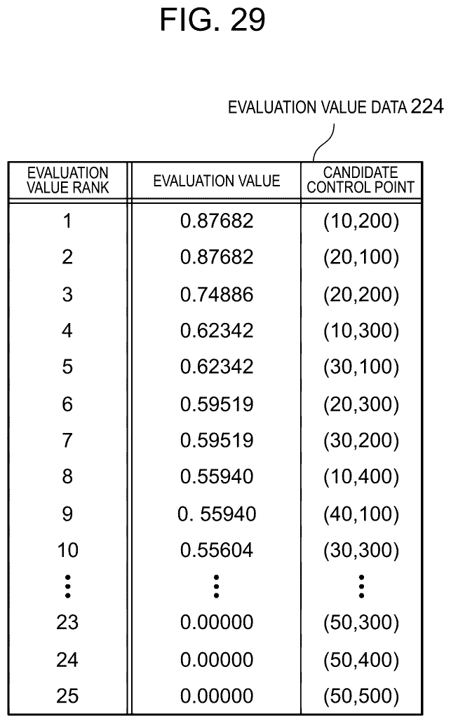

FIG. 29 is a diagram illustrating an example of changed evaluation value data 224 displayed on display unit 104.

Evaluation value output unit 13 may change evaluation value data 224 by sorting evaluation value data 224 by the evaluation value rank, and display changed evaluation value data 224 on display unit 104.

For example, as illustrated in FIG. 29, changed evaluation value data 224 indicates, for each rank of the evaluation values, the evaluation value corresponding to the rank and the candidate control point corresponding to the evaluation value. The ranks of the evaluation values are arranged in ascending order. That is, the candidate control points are arranged in descending order of the evaluation value. For example, evaluation value data 224 indicates the evaluation value “0.87682” corresponding to the rank “1” and a candidate control point (10,200) corresponding to the evaluation value. Further, evaluation value data 224 indicates the evaluation value “0.87682” corresponding to the rank “2” and a candidate control point (20,100) corresponding to the evaluation value.

Displaying of such evaluation value data 224 on display unit 104 allows the user to judge whether to continue or end the search for the optimal solution. Further, when continuing the search for the optimal solution, the user can select a candidate control point to be the next control point from all the displayed control point numbers, that is, all the candidate control points, based on the displayed evaluation values and the ranks. For example, the user selects a candidate control point corresponding to the largest evaluation value (that is, the evaluation value having the rank of 1). At this time, the user may perform an input operation on input unit 101a to sort the evaluation values of evaluation value data 224 in descending order. That is, evaluation value output unit 13 sorts the evaluation values in evaluation value data 224 such that the evaluation values are in descending order and the ranks are in ascending order. This makes it easy to find the largest evaluation value.

### [Application Example to Control of Time-Series Data]

Next, an application example to control of time-series data will be described.

In mass production sites, for example, there is a need to search for a set value (control point) of an optimal process condition in real time in order to stabilize product characteristics at an early stage when operation of a mass production line is resumed. This corresponds to a search problem of an optimal solution in consideration of time series, and can be understood as a problem of acquiring an optimal correspondence relationship (control point and characteristic point) at the next time point on the basis of past control information (information regarding the control point determined by a process condition setting value or the like) at each time.

Therefore, in the present exemplary embodiment, the optimum correspondence relationship is acquired using the evaluation value that can be evaluated while considering all relationships (correspondence) in the probability distribution using the predicted distribution obtained by the Kalman filter and the evaluation function obtained by the Bayesian optimization.

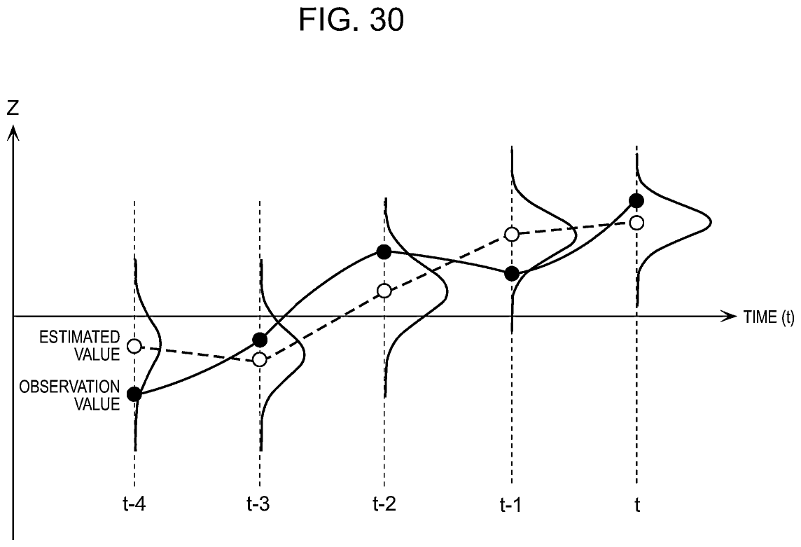

FIG. 30 is a diagram conceptually illustrating derivation of a predicted distribution by the Kalman filter.

As illustrated in FIG. 30, conceptually, the state estimation by the Kalman filter corresponds to sequentially estimating the average and the variance of the predicted distribution of the states from the observation value at the previous time every time (t−4, t−3, t−2, t−1, t). An estimated value can be obtained based on the average and variance of the predicted distribution. Note that sequentially estimating the average and variance of the predicted distribution of the states can also be interpreted as being corrected with the observation value at the previous time.

In other words, in the present exemplary embodiment, (the average and variance of) the predicted distribution is obtained by the Kalman filter every time a control result, that is, one or more control points used for control and characteristic points corresponding to the respective one or more control points are obtained. Then, the control point to be set next is selected on the basis of the evaluation function obtained by the Bayesian optimization.

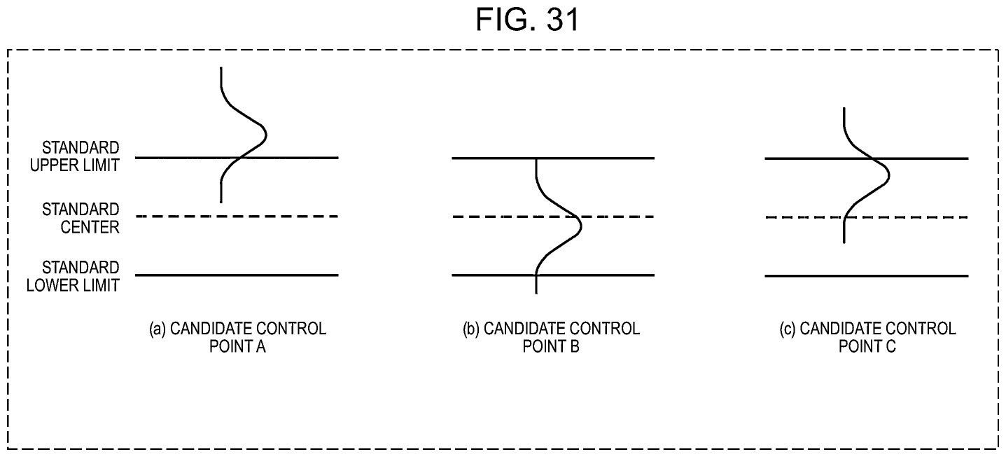

FIG. 31 is a diagram conceptually illustrating a relationship between a predicted distribution of a plurality of candidate control points and a standard range of product characteristics. Part (a) of FIG. 31 conceptually illustrates the predicted distribution of a candidate control point A, part (b) of FIG. 31 conceptually illustrates the predicted distribution of a candidate control point B, and part (c) of FIG. 31 conceptually illustrates the predicted distribution of a candidate control point C.

As illustrated in FIG. 31, when (the average and the variance of) the predicted distributions of the candidate control point A, the candidate control point B, and the candidate control point C are the same, the average of the predicted distributions is preferably close to the standard center from the viewpoint of stabilizing the product characteristics early. Therefore, among the candidate control point A, the candidate control point B, and the candidate control point C illustrated in FIG. 31, it is preferable that the candidate control point B is selected as the control point to be set next.

That is, in the Bayesian optimization, when the optimization purpose is within the standard range, the control is substantially equivalent to the control in which the standard center is set as the optimization target value, the optimization method (optimization purpose) is switched to minimization when the position of the immediately preceding characteristic point (observation value) is above the standard center, and the optimization purpose (optimization purpose) is switched to maximization when the position of the immediately preceding characteristic point is below the standard center.

### <Control Method 1 of Time-Series Data>

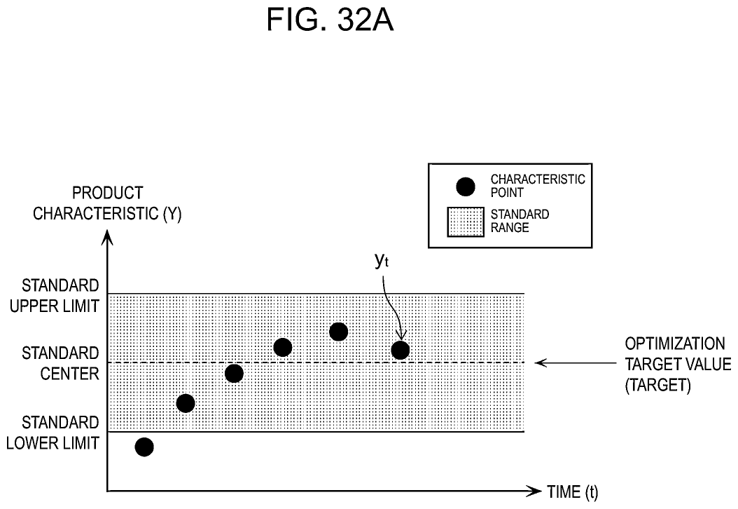

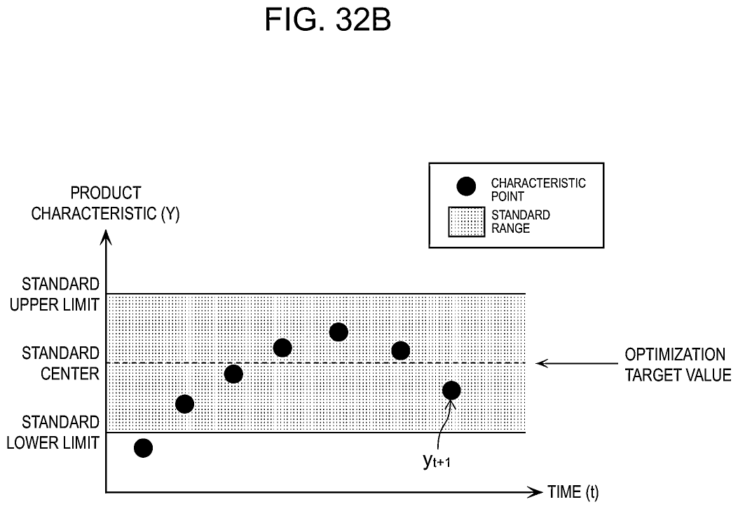

FIGS. 32A and 32B are diagrams for describing a control image of control method 1 for setting the optimization target value to the standard center according to the present exemplary embodiment. Note that FIGS. 32A and 32B illustrate a control image in a case where the number of product characteristics is one-dimensional in order to simplify the description.

When the optimization purpose is within the standard range, it can be interpreted as control for setting the standard center to the optimization target value, and switching the optimization method (optimization purpose) to minimization when the position of the immediately preceding characteristic point (observation value) is above the standard center, and switching the optimization purpose (optimization purpose) to maximization when the position of the immediately preceding characteristic point is below the standard center. Such a control method is hereinafter referred to as control method 1 of time-series data.

That is, as illustrated in FIGS. 32A and 32B, in the control method 1 of time-series data, when the optimization purpose is within the standard range, the standard center is set to the optimization target value. Specifically, in the example illustrated in FIG. 32A, since the immediately preceding characteristic point yₜ is above the standard center, control may be performed by setting the optimization method (optimization purpose) to minimization. On the other hand, in the example illustrated in FIG. 32B, since the immediately preceding characteristic point yₜ₊₁ is lower than the standard center, control may be performed by setting the optimization method (optimization purpose) to maximization.

As described above, in the control method 1 of time-series data, the fact that the optimization purpose is within the standard range is interpreted as a control method in which the optimization target value is the standard center, and the optimization method is switched to maximization or minimization according to the position of the immediately preceding characteristic point (observation point).

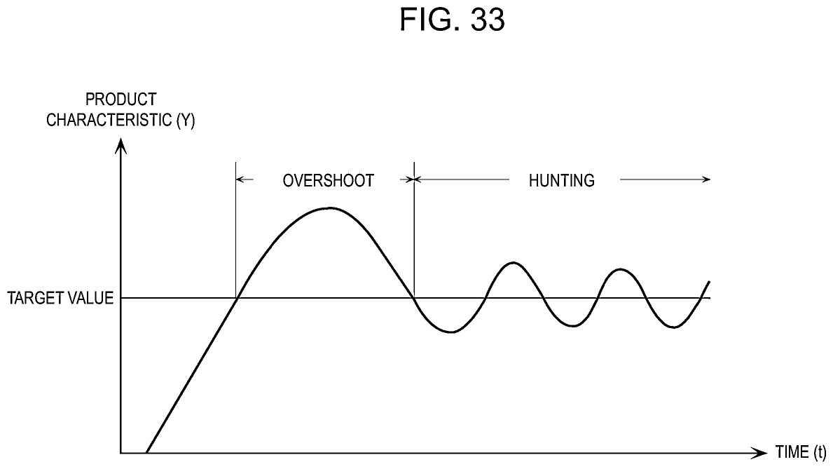

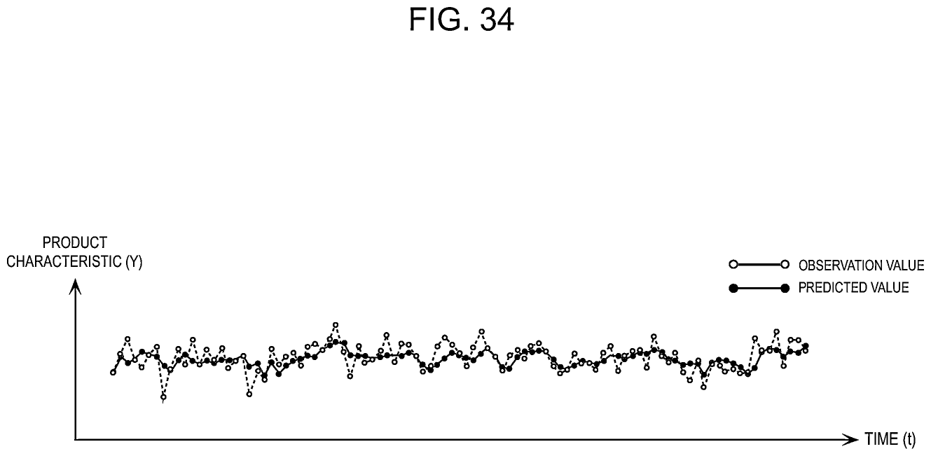

FIG. 33 is a diagram conceptually illustrating an overshoot phenomenon and a hunting phenomenon. FIG. 34 is a diagram conceptually illustrating a noise canceling effect which is a characteristic of a Kalman filter.

If control is performed by Bayesian optimization in a case where the optimization purpose is within the standard range by the interpretation of the above control method 1 using the predicted distribution obtained by the Kalman filter, basically, operation is successful. However, when the control by the control method 1 is performed, an overshoot phenomenon in which the observation value goes beyond the standard center occurs as illustrated in FIG. 33, for example. This is because, as illustrated in FIG. 34, the Kalman filter has a characteristic of predicting (estimating a predicted distribution) without being excessively affected by the fluctuation of the observation value, that is, a noise canceling effect. That is, when the Kalman filter is used, the behavior of the predicted distribution is easily calculated to be smaller than the behavior of the observation value. Therefore, in a case where control is performed by setting the standard center as the optimized target value as in the control method 1, it is determined that the predicted value has not yet crossed the standard center even after the observation value has crossed the standard center, and the predicted value is calculated so as to continuously rise or fall for a while. Then, the predicted value is calculated such that the trajectory of the predicted value is corrected for the first time when the predicted value crosses the standard center.

### <Control Method 2 of Time-Series Data>

In order to suppress the overshoot phenomenon that occurs in the control method 1 of time-series data, a control method 2 that is a second best measure in which the interpretation in a case where the optimization purpose is within the standard range is changed is used. That is, in the control method 2 of time-series data, when the optimization purpose is within the standard range, control may be performed such that the optimization target value is set to the standard lower limit value when the immediately preceding characteristic point (observation value) is above the standard center, and the optimization target value is set to the standard upper limit value when the immediately preceding characteristic point (observation value) is below the standard center. Note that the optimization method (optimization purpose) is similar to the control method 1, and it is only required to perform control to switch the optimization method (optimization purpose) to minimization when the position of the immediately preceding characteristic point (observation value) is above the standard center and the optimization purpose (optimization purpose) to maximization when the position of the immediately preceding characteristic point is below the standard center.

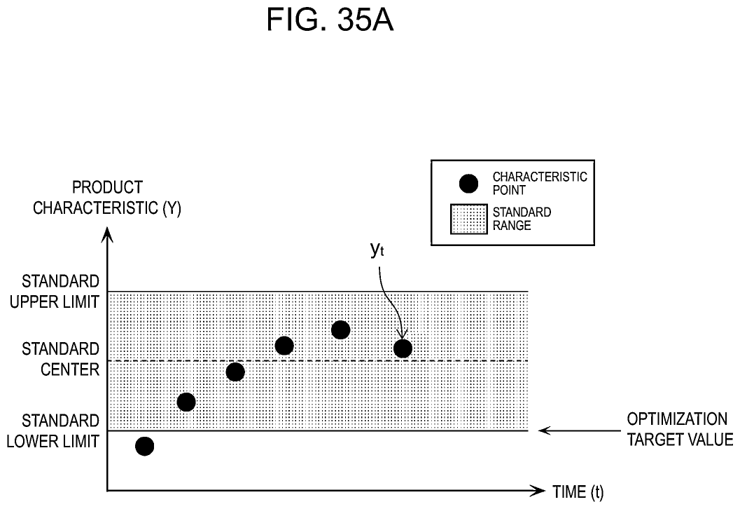

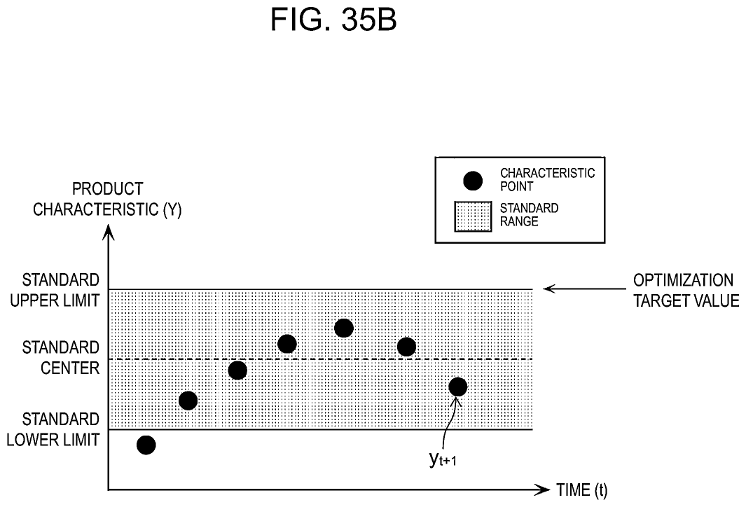

FIGS. 35A and 35B are diagrams for describing a control image of the control method 2 for setting the optimization target value to the upper and lower limits of the standard according to the present exemplary embodiment. FIGS. 35A and 35B also illustrate a control image in a case where the number of product characteristics is one-dimensional in order to simplify the description.

In the control method 2 of time-series data, when the optimization purpose is within the standard range and the immediately preceding characteristic point yₜ is above the standard center as in the example illustrated in FIG. 35A, the standard lower limit is set to the optimization target value and control is performed. On the other hand, as illustrated in FIG. 35B, when the immediately preceding characteristic point yₜ₊₁ is below the standard center, the standard upper limit is set to the optimization target value, and control is performed.

As described above, in the control method 2 of time-series data, the fact that the optimization purpose is within the standard range is interpreted as a control method in which the optimization target value is switched to the standard upper limit value or the standard lower limit value according to the position of the immediately preceding characteristic point (observation point). Furthermore, in the control method 2 of time-series data, in a case where the optimization purpose is within the standard range, it is interpreted that the optimization method is a control method that switches to maximization or minimization according to the position of the immediately preceding characteristic point (observation point).

As a result, in the control method 2, as compared with the control method 1 in which the trajectory correction of the predicted value is calculated for the first time when the predicted value crosses the standard center, the timing of the trajectory correction of the predicted value becomes earlier, so that the overshoot phenomenon can be suppressed.

However, when the control by the control method 2 is performed, for example, as illustrated in FIG. 33, a hunting phenomenon in which the observation value vibrates near the standard center is likely to occur. This is because when the control by the control method 2 is performed, the optimization target value is set at the position of the standard lower limit value or the standard upper limit value far from the standard center, and thus, a candidate control point at which the characteristic point rapidly rises or falls is easily selected from the plurality of candidate control points at all times as the control point to be set next.

### <Control Method 3 of Time-Series Data>

In a case where the optimization purpose is within the standard range, an overshoot phenomenon occurs when the optimization target value is set to the standard center as in the control method 1, and a hunting phenomenon occurs when the optimization target value is set to the standard upper and lower limits as in the control method 2. Therefore, it is expected that the overshoot phenomenon and the hunting phenomenon can be suppressed by performing the control method 3 in which the initial value of the optimization target value is set to the upper and lower limits of the standard and the optimization target value is gradually moved to the standard center according to the rule described below. That is, in the control method 3 of time-series data, when the optimization purpose is within the standard range, control is performed to switch the optimization method (optimization purpose) to maximization or minimization according to the position of the immediately preceding characteristic value while moving the optimization target value from the standard upper and lower limit values to the standard center.

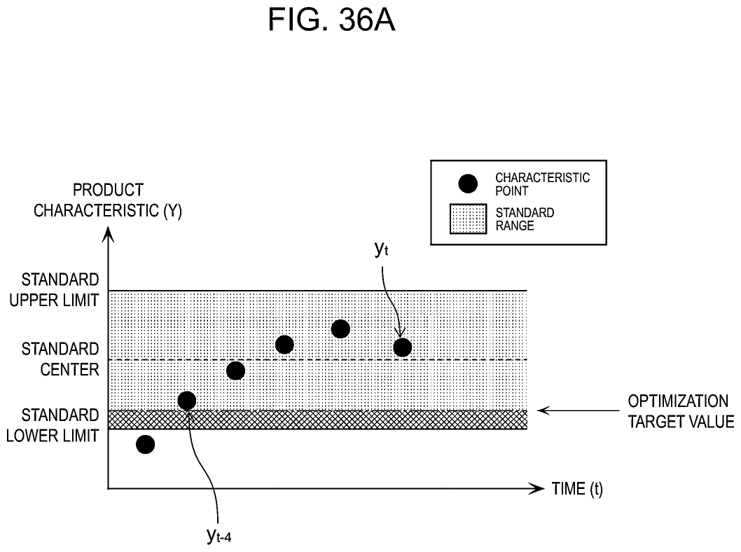

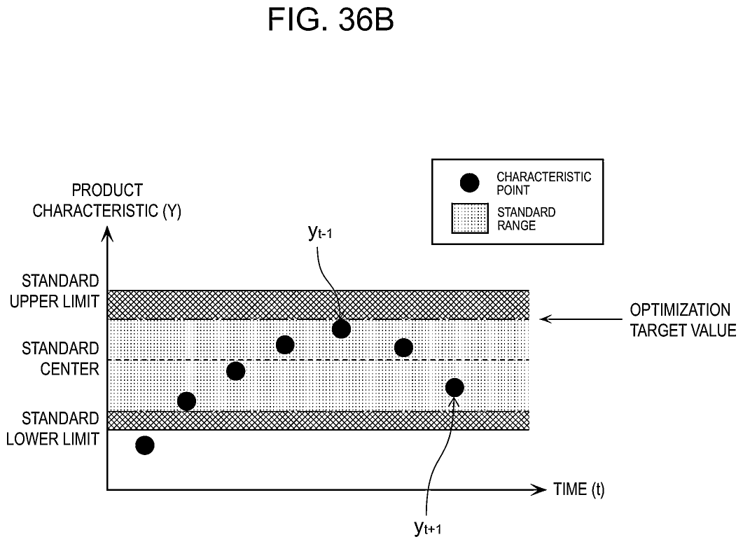

FIGS. 36A and 36B are diagrams for describing a control image of the control method 3 for gradually moving the optimization target value to the standard center according to the present exemplary embodiment. FIGS. 36A and 36B also illustrate a control image in a case where the number of product characteristics is one-dimensional in order to simplify the description.

In the control method 3 of time-series data, when the optimization purpose is within the standard range, control is performed while gradually moving the optimization target value to the standard center. For example, as illustrated in FIG. 36A, when the immediately preceding characteristic point yₜ is above the standard center and the characteristic point yₜ₋₄ is a minimum value within the standard range in the past control, the control is performed by setting the minimum value as the optimization target value. Note that the optimization method (optimization purpose) is controlled as being minimization because the immediately preceding characteristic point yₜ is above the standard center. On the other hand, as in the example illustrated in FIG. 36B, when the immediately preceding characteristic point yₜ₊₁ is lower than the standard center and the characteristic point yₜ₋₁ is the maximum value within the standard range in the past control, the control may be performed by setting the maximum value as the optimization target value. Note that the optimization method (optimization purpose) is controlled as being maximization because the immediately preceding characteristic point yₜ₊₁ is below the standard center.

Hereinafter, a method for moving the optimization target value to the standard center will be described.

As the simplest idea, there is a method for equally dividing the distance from the standard upper and lower limits to the standard center and moving the distance at a constant speed for each time. However, in this method, it is necessary for the analyst to determine the number of divisions, that is, the moving speed. If the speed at which the optimization target value is moved is too fast, the speed becomes substantially equivalent to the case where the optimization target value is set to the standard center from the beginning, so that the overshoot phenomenon is likely to occur. On the contrary, if the speed at which the optimization target value is moved is too slow, the speed becomes substantially equivalent to the case where the optimization target value is set to the standard upper and lower limits from the beginning, so that the hunting phenomenon is likely to occur. Therefore, there arises a problem that the analyst needs to select the number of divisions for suppressing both the overshoot phenomenon and the hunting phenomenon. In addition, the number of divisions for suppressing both the overshoot phenomenon and the hunting phenomenon varies depending on the target task, and trial and error occurs by the analyst, which is not realistic.

On the other hand, in the control method 3 described above, when the transition of the characteristic point changes from rise to fall, the maximum point is set to the optimization target value for the next rise, and conversely, when the transition of the characteristic point changes from fall to rise, the minimum point is set to the optimization target value for the next fall. As described above, when the control by the control method 3 is performed, the overshoot phenomenon and the hunting phenomenon can be suppressed without causing the operation depending on the analyst.

### <Control Method 3 Utilizing EHVIC>

In the control method 3 described above, in a case where the position of the maximum point or the minimum point in the initial stage is close to the standard center, it is substantially equivalent to a case where the optimization target value is set to the standard center from the beginning. Therefore, when the position of the maximum point or the minimum point in the initial stage is close to the standard center, an overshoot phenomenon may occur.

Therefore, the idea of EHVIC, which is an acquisition function of Bayesian optimization, is utilized in the control method 3 of time-series data. Hereinafter, control in a case where the number of product characteristics is two or more dimensions will be described as an example.

In the idea of EHVIC, when a plurality of product characteristics are simultaneously maximized or minimized, a region in a characteristic space to be evaluated is partitioned such that an optimal solution search efficiently proceeds based on observed Pareto points. For example, when there are two product characteristics, even if one of the product characteristics obtains a characteristic point extremely close to the optimization target value, the characteristic point is not partitioned over the entire characteristic space by the value, but partitioned stepwise by the coordinates of all pareto points. By utilizing this idea of the EHVIC, in the control method 3 of time-series data, the optimization target value may be suppressed from rapidly moving from the standard upper and lower limits, which are the initial values, to the standard center.

However, as described above, the EHVIC has a problem that the calculation cost increases exponentially according to the number of product characteristics. Therefore, by using the region reduction rule that is a rule for reducing the active region, the calculation cost can be reduced to polynomial function order while maintaining the search accuracy.

When the number of product characteristics is two or more dimensions, the optimization target value cannot be uniquely determined if the region reduction rule described above is applied as it is. Therefore, in the following, a method in which the optimization target value can be uniquely determined even if the above-described region reduction rule is applied in a case where the number of product characteristics is two or more dimensions will be described.

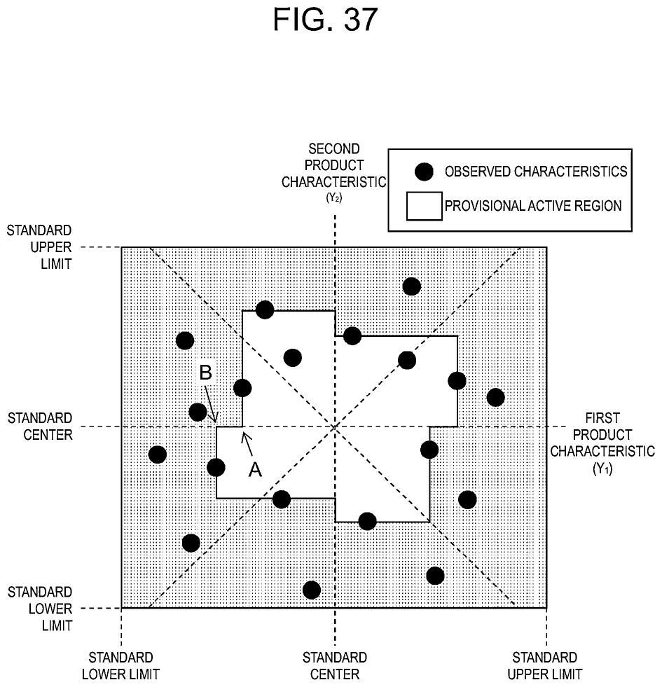

FIG. 37 is a diagram for explaining that there are a plurality of candidates for the optimization target value in a case where the number of product characteristics is two or more dimensions.

When the number of product characteristics is D dimensions, the entire characteristic space can be divided into 20 divided regions by dividing each product characteristic into an upper side and a lower side of the standard center. In each divided region, the region reduction rule is applied, and the opposite Pareto boundary is set as the optimization target value for each product characteristic. FIG. 37 illustrates four divided regions in a case where the number of product characteristics is two or more dimensions. In addition, FIG. 37 illustrates a pareto boundary and an active region calculated from observed characteristic points existing in each of the four divided regions. Note that the Pareto boundary illustrated in FIG. 37 is a provisional Pareto boundary in which the optimization target value is not uniquely determined, and thus is hereinafter referred to as a provisional Pareto boundary. In addition, the active region under the provisional pareto boundary is hereinafter referred to as a provisional active region. Further, a non-provisional pareto boundary is referred to as a combined pareto boundary, and an active region under the combined pareto boundary is referred to as a combined active region.

For example, when the region reduction rule is applied in a case where the immediately preceding characteristic point in the first product characteristic (Y₁) is located above the standard center, the optimization method (optimization purpose) in the first product characteristic (Y₁) may be determined to be minimization, and the optimization target value may be determined from the pareto boundary existing in the region below the standard center. However, for example, as illustrated in FIG. 37, when there are two provisional pareto boundaries indicated by A and B in the first product characteristic (Y₁), there are two candidates for the optimization target value. In this case, among the provisional pareto boundaries indicated by A and B, a boundary closer to the standard center (provisional pareto boundary of A), a boundary farther from the standard center (provisional pareto boundary of B), a boundary between intermediate positions thereof, or the like may be defined as the combined pareto boundary. The same applies to the second product characteristic (Y₂), and thus the description thereof will be omitted.

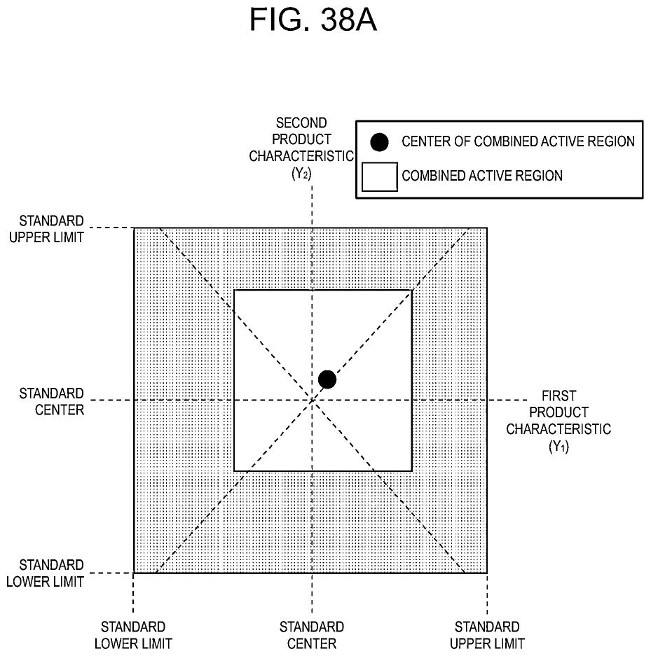

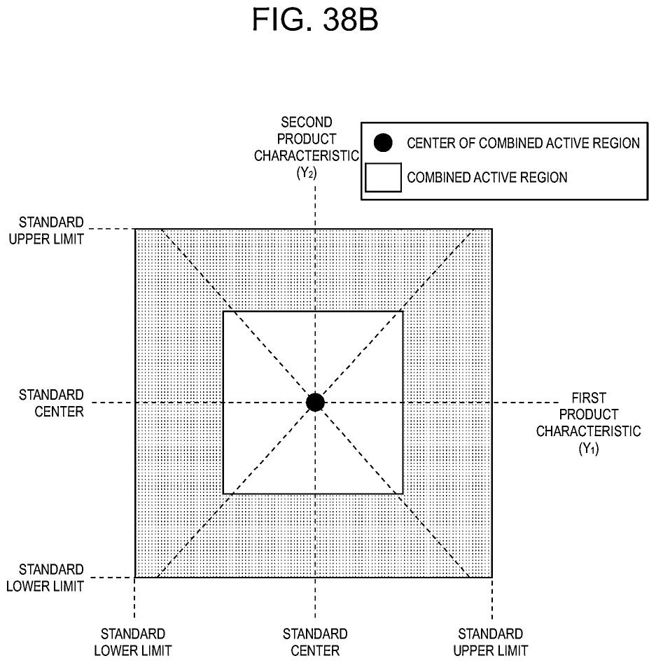

FIG. 38A is a diagram illustrating a combined active region in a case where the center does not coincide with the standard center. FIG. 38B is a diagram illustrating a combined active region in a case where the center coincides with the standard center.

Further, in the example shown in FIG. 37, it is better not to individually define the combined pareto boundaries above and below the standard center of the first product characteristic (Y₁) and above and below the standard center of the second product characteristic (Y₂). This is because, as illustrated in FIG. 38A, the combined active region under the individually defined combined pareto boundary is a single rectangle, but the center thereof is likely to be at a position different from the standard center. In addition, when the control of the time-series data is executed by the control method 3 in a case where the center of the combined active region is at a position different from the standard center, the control proceeds so that the observation value is driven toward the center of the combined active region. For this reason, there is a high possibility that control is performed while deviating from the standard center which is the original target (optimization target value).

In view of this, in the control method 3 utilizing the EHVIC in the present exemplary embodiment, the combined pareto boundary in each product characteristic is uniquely defined in the region above the standard center and the region below the standard center. For example, in the example shown in FIG. 37, in the first product characteristic (Y₁), with respect to a total of four Y₁ coordinates including two provisional pareto boundaries existing in a region above the standard center and two provisional pareto boundaries existing in a region below the standard center, a Y₁ coordinate larger than the standard center by an intermediate value such as an average value of distances from the standard center may be defined as a combined pareto boundary of the upper region. Similarly, the Y₁ coordinate smaller than the standard center by the intermediate value may be defined as the combined pareto boundary of the lower region. In this manner, the combined pareto boundary of the lower region as the combined pareto boundary of the upper region is determined so as to be equidistant from the standard center of the first product characteristic (Y₁). The same applies to the second product characteristic (Y₂), and thus description thereof will be omitted.

As described above, by defining the combined pareto boundary together in the upper region and the lower region from the standard center, the combined active region under the defined combined pareto boundary can be made into a single rectangle and the center thereof can be matched with the standard center as illustrated in FIG. 38B.

Note that the method of defining the combined pareto boundary together in the upper region and the lower region from the standard center is not limited to the case of using the intermediate position of the Y₁ coordinate of the plurality of provisional pareto boundaries, and the combined pareto boundary passing through the position at which the distance from the standard center is the closest value or the farthest value may be defined. In a case where the combined pareto boundary passing through the position (Y₁ coordinate) having the closest value is defined, the overshoot phenomenon is likely to occur, and in a case where the combined pareto boundary passing through the position (Y₁ coordinate) having the farthest value is defined, the hunting phenomenon is likely to occur. For this reason, if there is no particular reason, a combined pareto boundary passing through the position having the intermediate value described above may be defined.

As described above, the overshoot phenomenon occurs simply by combining the Kalman filter and the Bayesian optimization. Therefore, by performing the control method 3 of time-series data, the initial value of the optimization target value is set to the upper and lower limits of the standard and is gradually moved to the standard center, so that the hunting phenomenon can also be suppressed. In addition, according to the control method 3 of time-series data, it is possible to realize a speed-up algorithm in which the calculation cost is suppressed by using the acquisition function of the Bayesian optimization for the quantitative evaluation of the candidate control points and further applying the region reduction rule.

In this way, by sequentially calculating the predicted distribution obtained by the Kalman filter and the evaluation value obtained by using the Bayesian optimization from the predicted distribution, the candidate control point to be set next is provided to the analyst (user) in the ranking order or the like and is selected. Therefore, since it is possible to quantitatively evaluate the candidate control point at which the occurrence of the overshoot phenomenon or the hunting phenomenon can be suppressed without depending on the analyst, it is possible to suppress the occurrence of the overshoot phenomenon or the hunting phenomenon and to realize the stable and efficient real-time control of the time-series data.

### [Effects and the Like]

As described above, the evaluation device according to the present exemplary embodiment is an evaluation device that evaluates, by Bayesian optimization, a plurality of unknown characteristic points corresponding to a plurality of candidate control points at a second time subsequent to a first time based on known characteristic points corresponding to controlled control points at the first time, the evaluation device including: a first reception means that acquires control result data indicating the controlled control point at the first time and the known characteristic point at the first time; a second reception means that acquires purpose data indicating an optimization purpose, the unknown characteristic point indicating values of one or a plurality of product characteristics, and at least one product characteristic having the optimization purpose; a third reception means that acquires constraint condition data indicating a constraint condition applied to the at least one product characteristic; a fourth reception means that acquires region reduction rule data indicating a division method of a characteristic space represented by at least one product characteristic and indicating a dimension for reducing an active region for each region of the characteristic space divided by the division method; a calculation means that calculates an evaluation value of each of the plurality of unknown characteristic points based on the control result data, the purpose data, the constraint condition data, and the region reduction rule data; and an output means that outputs the evaluation value, in which the calculation means applies weighting according to a degree of conformity of the constraint condition to an evaluation value for the at least one product characteristic.

As a result, the calculation means can calculate the evaluation values of the plurality of unknown characteristic points at the second time subsequent to the first time on the basis of the control result data, the purpose data, the constraint condition data, and the region reduction rule data. When the evaluation values of the plurality of unknown characteristic points are calculated, weighting according to the degree of conformity of the constraint condition is applied to the evaluation value for at least one product characteristic, and the at least one product characteristic has an optimization purpose. Therefore, the Kalman filter and the Bayesian optimization can be applied to an optimization problem in which a constraint condition is applied to time-series product characteristics having a purpose of the optimization problem. In this way, since the evaluation values of the plurality of unknown characteristic points can be calculated from the known characteristic points corresponding to the controlled control points at the first time as the past control result information, the candidate control points to be set next can be quantitatively analyzed.

Further, in the present exemplary embodiment, the constraint condition is a standard range, and the optimization purpose includes a first purpose of keeping the product characteristics within the standard range and a second purpose of minimizing or maximizing the product characteristics. Then, for each of at least one product characteristic, evaluation value calculating unit 12 calculates the evaluation value by performing weighting processing different from one another among (i) a case where the interval of the product characteristic used for calculating the evaluation value is out of the standard range, (ii) a case where the interval is within the standard range and the optimization purpose is a first purpose, and (iii) a case where the interval is within the standard range and the optimization purpose is a second purpose. That is, the evaluation value is calculated on the basis of (Equation 6) and (Equation 7) described above. As a result, regardless of whether the optimization purpose of the product characteristics is the first purpose or the second purpose, the evaluation value of the candidate control point can be appropriately calculated on the basis of the Bayesian optimization. That is, the evaluation value of the candidate control point can be appropriately calculated based on the Bayesian optimization regardless of whether the optimization purpose of the product characteristics is within the standard range or whether the optimization purpose is maximization or minimization. In addition, in the case of (iii), since the interval of the product characteristic falls within the standard range and the optimization purpose is the second purpose, unlike the method of Non-Patent Document 2, the evaluation value can be quantitatively and appropriately calculated even when the product characteristic with the optimization purpose of maximization or minimization has the standard range as the constraint condition.

As a result, the present invention can also be applied to an optimization problem having a constraint condition such as a standard range. That is, the application scene can be extended, and quantitative evaluation for improving the search efficiency of the optimal solution can be performed.

The calculation means may calculate a predicted distribution at the plurality of candidate control points using a Kalman filter, and calculate the evaluation value using the calculated predicted distribution.

As a result, it is possible to sequentially calculate the predicted distribution obtained by the Kalman filter and the evaluation value obtained from the predicted distribution by using the Bayesian optimization. Therefore, the candidate control point to be set as the control point next can be selected based on the evaluation value. That is, since the evaluation value calculated for each candidate control point is output, the user of the evaluation device can select the candidate control point as the next control point based on the evaluation values, and use the characteristic point obtained by the control using the control point for the calculation of the evaluation value of each candidate control point. By repetition of such a control and calculation and output of an evaluation value, it is possible to obtain a solution of a candidate control point that satisfies an optimization purpose of each product characteristic, that is, an optimal solution.

In addition, in the calculation of the acquisition function, the entire characteristic space is divided into the active region and the inactive region at the pareto boundary defined by a certain rule from the pareto point and the pareto boundary. Therefore, since the calculation means can further change the definition of the pareto boundary on the basis of the region reduction rule data, the acquisition function in the Bayesian optimization can be calculated only by calculating the expected value of the volume of the single hyper-cuboid. As a result, the calculation means can suppress the calculation amount of the acquisition function while maintaining the search efficiency, so that the evaluation of the unknown characteristic point can be performed at high speed.

Evaluation value calculating unit 12 may calculate the evaluation value of each candidate control point using a Monte Carlo method. As a result, since the Monte Carlo method is an approximate method, the evaluation value can be calculated approximately even when it is difficult to calculate the evaluation value analytically. That is, the calculation can be approximately performed by using the Monte Carlo method without strictly performing the operations of (Equation 6) and (Equation 7). Note that, as long as the approximation method is used, not only the Monte Carlo method but also other methods may be used.

### EXAMPLES

As an example of processing when the region reduction rule is applied to above control method 3 to search for the optimum solution of the product characteristic, an example of processing of defining the active region from the region reduction rule when a set of control results is added will be described.

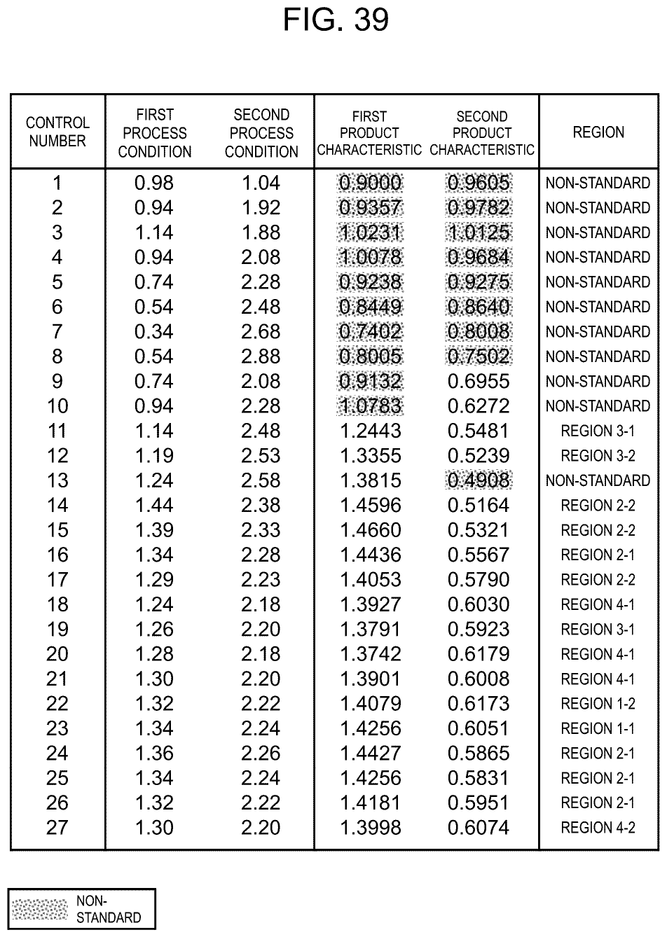

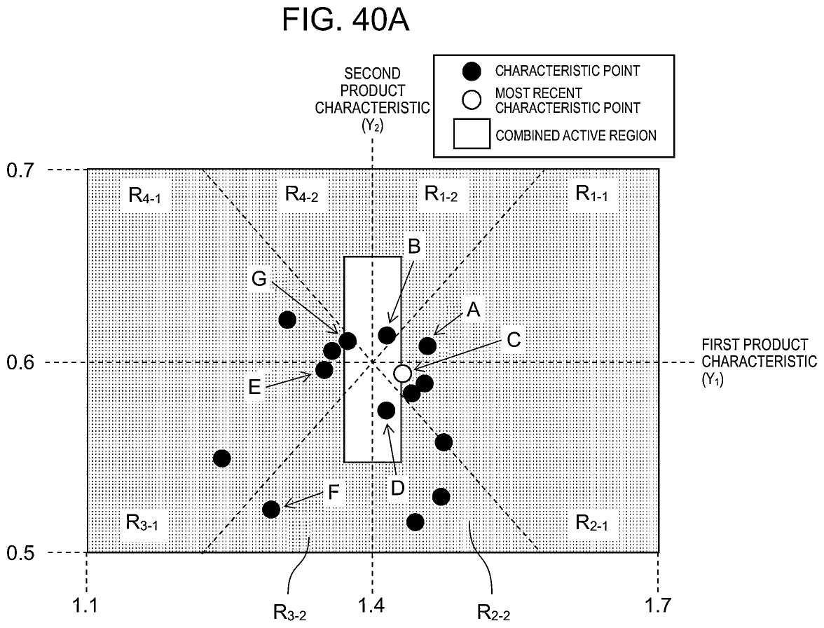

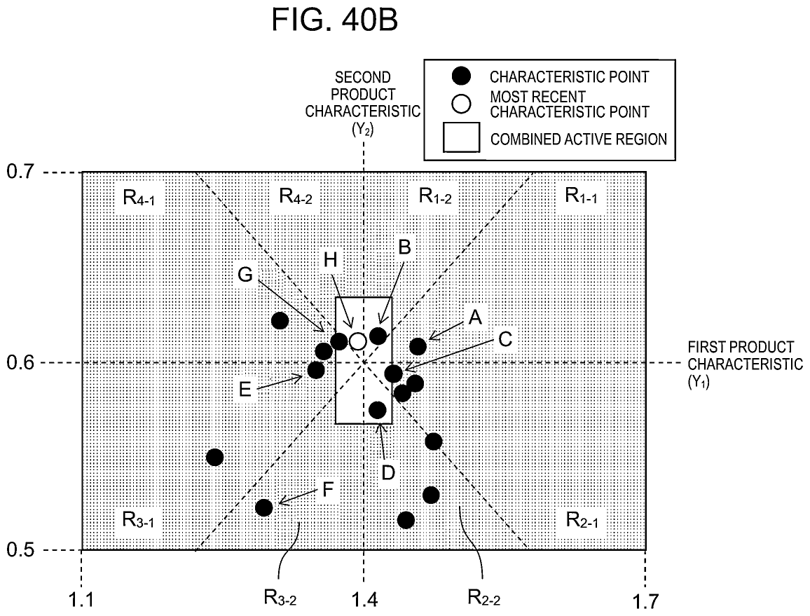

FIG. 39 is a diagram illustrating an example of a control result data sheet obtained when an optimal solution is searched according to the example of the present exemplary embodiment. FIG. 40A is a diagram illustrating the combined active regions at the time points when the control results up to the twenty-sixth control result in FIG. 39 have been obtained. FIG. 40B is a diagram illustrating the combined active region at the time point when the twenty-seventh control result in FIG. 39 is obtained. Note that the calculation processing of the predicted distribution using the Kalman filter and the calculation processing of the acquisition function using EHVI and EHVIC are as described above, and thus the description thereof will be omitted. In FIGS. 40A and 40B, non-standard characteristic points are omitted.

FIG. 39 illustrates, for each control number, a process condition of a control point used in the control identified by the control number and a product characteristic of a characteristic point that is a control result obtained by the control. FIG. 39 illustrates a case where the number of process conditions is two (first process condition and second process condition) and the number of product characteristics is two (first product characteristic, second product characteristic 2). The optimization purpose is minimization for both the first product characteristic (Y₁) and the second product characteristic (Y₂), and the standard range of the first product characteristic (Y₁) is set to 1.1 to 1.7 and the standard range of the second product characteristic (Y₂) is set to 0.5 to 0.7. In addition, the initial value of the combined active region is a standard range, that is, the initial value of the combined pareto boundary is a standard upper and lower limit of each dimension. The standard range in the present exemplary embodiment can be expressed as (Equation 11). Furthermore, the regions (regions R₁₋₁ to R₄₋₂) to which the region reduction rule in FIGS. 40A and 40B is applied are defined as (Equation 12).

$$\begin{matrix}[ Math . 17 ] & \\ R = {R}_{1 - 1} ⋃ {R}_{1 - 2} ⋃ {R}_{2 - 1} ⋃ {R}_{2 - 2} ⋃ {R}_{3 - 1} ⋃ {R}_{3 - 2} ⋃ {R}_{4 - 1} ⋃ {R}_{4 - 2} & ( Equation 11 )\end{matrix}$$

$$\begin{matrix}[ Math . 18 ] & \\ \begin{matrix}Region 1 - 1 : {R}_{1 - 1} = \{ y ∈ {ℝ}^{2} \vert 1.4 \leq {y}_{1} \leq 1.7 , 0.6 \leq {y}_{2} \leq 0.7 , \vert {y}_{1} - 1.4 \vert \geq \vert {y}_{2} - 0.6 \vert \} \\ Region 1 - 2 : {R}_{1 - 2} = \{ y ∈ {ℝ}^{2} \vert 1.4 \leq {y}_{1} \leq 1.7 , 0.6 \leq {y}_{2} \leq 0.7 , \vert {y}_{1} - 1.4 \vert < \vert {y}_{2} - 0.6 \vert \} \\ Region 2 - 1 : {R}_{2 - 1} = \{ y ∈ {ℝ}^{2} \vert 1.4 \leq {y}_{1} \leq 1.7 , 0.5 \leq {y}_{2} \leq 0.6 , \vert {y}_{1} - 1.4 \vert \geq \vert {y}_{2} - 0.6 \vert \} \\ Region 2 - 2 : {R}_{2 - 2} = \{ y ∈ {ℝ}^{2} \vert 1.4 \leq {y}_{1} \leq 1.7 , 0.5 \leq {y}_{2} \leq 0.6 , \vert {y}_{1} - 1.4 \vert < \vert {y}_{2} - 0.6 \vert \} \\ Region 3 - 1 : {R}_{3 - 1} = \{ y ∈ {ℝ}^{2} \vert 1.1 \leq {y}_{1} \leq 1.4 , 0.5 \leq {y}_{2} \leq 0.6 , \vert {y}_{1} - 1.4 \vert \geq \vert {y}_{2} - 0.6 \vert \} \\ Region 3 - 2 : {R}_{3 - 2} = \{ y ∈ {ℝ}^{2} \vert 1.1 \leq {y}_{1} \leq 1.4 , 0.5 \leq {y}_{2} \leq 0.6 , \vert {y}_{1} - 1.4 \vert \geq \vert {y}_{2} - 0.6 \vert \} \\ Region 4 - 1 : {R}_{4 - 1} = \{ y ∈ {ℝ}^{2} \vert 1.1 \leq {y}_{1} \leq 1.4 , 0.6 \leq {y}_{2} \leq 0.7 , \vert {y}_{1} - 1.4 \vert \geq \vert {y}_{2} - 0.6 \vert \} \\ Region 4 - 2 : {R}_{4 - 2} = \{ y ∈ {ℝ}^{2} \vert 1.1 \leq {y}_{1} \leq 1.4 , 0.6 \leq {y}_{2} \leq 0.7 , \vert {y}_{1} - 1.4 \vert \geq \vert {y}_{2} - 0.6 \vert \}\end{matrix} & ( Equation 12 )\end{matrix}$$

In the regions R₁₋₁ and R₂₋₁, the minimum value of the coordinates of the first product characteristic (Y₁) among the characteristic points in each region is set as a provisional pareto boundary. In the regions R₃₋₁ and R₄₋₁, the maximum value of the coordinates of the first product characteristic (Y₁) among the characteristic points in each region is set as the provisional pareto boundary. In the regions R₁₋₂ and R₄₋₂, the minimum value of the coordinates of the second product characteristic (Y₂) among the characteristic points in each region is set as the provisional pareto boundary. In the regions R₂₋₂ and R₃₋₂, the maximum value of the coordinates of the second product characteristic (Y₂) among the characteristic points in each region is set as the provisional pareto boundary.

In addition, for each dimension, a boundary passing through coordinates separated from the standard center by the average value of the distances from the standard center of the provisional pareto boundary is defined as a combined pareto boundary, and a rectangular region defined thereby is defined as a combined active region. Hereinafter, the coordinate in the first product characteristic (Y₁) is referred to as a Y₁ coordinate, and the coordinate in the second product characteristic (Y₂) is referred to as a Y₂ coordinate.

First, in the control result data illustrated in FIG. 39, it is assumed that control results up to the control result of the twenty-sixth control number are given. The combined active region at this time point is the combined active region shown in FIG. 40A.

Characteristic points A, B, C, D, E, F, and G illustrated in FIG. 40A are pareto points in the region R₁₋₁, the region R₁₋₂, the region R₂₋₁, the region R₂₋₂, the region R₃₋₁, the region R₃₋₂, and the region R₄₋₁ illustrated in FIG. 40A. In the example illustrated in FIG. 40A, there is no pareto point in the region R₄₋₂. In the example illustrated in FIG. 40A, the combined pareto boundary of the first product characteristic (Y₁) is a position passing through the Y₁ coordinate separated from the standard center by the average value of the distances between the Y₁ coordinates of the characteristic points A, C, E, and G and the standard center in the first product characteristic (Y₁). The combined pareto boundary of the second product characteristic (Y₂) is a position passing through the Y₂ coordinate separated from the standard center by an average value of distances between the Y₂ coordinate of the characteristic points B, D, and F, the standard upper limit value in the second product characteristic (Y₂), and the standard center in the second product characteristic (Y₂).

Specifically, the upper limit and the lower limit in the first product characteristic (Y₁) of the combined active region illustrated in FIG. 40A are as follows. That is, the upper limit of the first product characteristic (Y₁) is the Y₁ coordinate (1.417975) obtained by adding the average value (0.017975) of the distances between the Y₁ coordinate (1.4256, 1.4181, 1.3791, 1.3927) of the characteristic points A, C, E, and G and the standard center (1.4000) from the standard center. The lower limit of the first product characteristic (Y₁) is the Y₁ coordinate (1.382025) obtained by subtracting the average value (0.017975) of the distances between the Y₁ coordinate (1.4256, 1.4181, 1.3791, 1.3927) of the characteristic points A, C, E, and G and the standard center (1.4000) from the standard center. The upper limit and the lower limit in the second product characteristic (Y₂) of the combined active region illustrated in FIG. 40A are as follows. That is, the upper limit of the second product characteristic (Y₂) is the Y₂ coordinate (0.653600) obtained by adding the Y₂ coordinate (0.6173, 0.5790, 0.5239) of the characteristic points B, D, and F and the average value (0.053600) of the distances between the standard upper limit value (0.7) and the standard center (0.6000) from the standard center. The lower limit of the second product characteristic (Y₂) is the Y₂ coordinate (0.546400) obtained by subtracting the Y₂ coordinate (0.6173, 0.5790, 0.5239) of the characteristic points B, D, and F and the average value (0.053600) of the distances between the standard lower limit value (0.5) and the standard center (0.6000) from the standard center.

As illustrated in FIG. 39, the characteristic point having the latest twenty-sixth control number falls within the standard range, and belongs to region R₂₋₁. The characteristic point having the twenty-sixth control number corresponds to characteristic point C in FIG. 40A, and is located above the standard center in the first product characteristic (Y₁) and below the standard center in the second product characteristic (Y₂). Therefore, the optimization method (optimization purpose) in the first product characteristic (Y₁) and the second product characteristic (Y₂) is set to minimization and maximization. The optimization target value in the first product characteristic (Y₁) is set to coordinates (1.382025) of the lower limit of the first product characteristic (Y₁) in the combined active region. The optimization target value in the second product characteristic (Y₂) is set to the coordinates (0.653600) of the upper limit of the second product characteristic (Y₂) in the combined active region.

Next, evaluation value calculating unit 12 calculates a predicted distribution of the twenty-seventh characteristic point for each candidate control point using an update equation of the Kalman filter such as (Equation 5) on the basis of the control results up to the control result having the twenty-sixth control number. Evaluation value calculating unit 12 calculates an acquisition function for each candidate control point using the calculated predicted distribution and an update equation of Bayesian optimization such as (Equation 7). The candidate control point having the maximum evaluation value obtained from the calculated acquisition function is adopted as the twenty-seventh control point.

Next, in the control result data illustrated in FIG. 39, when the control result having the twenty-seventh control number is obtained, similar processing is executed. The combined active region at this time point is the combined active region shown in FIG. 40B.

As illustrated in FIG. 39, the characteristic point having the latest twenty-seventh control number falls within the standard range, and belongs to region R₄₋₂. The characteristic point having the twenty-seventh control number corresponds to characteristic point H in FIG. 40B, and is a new pareto point belonging to region R₄₋₂. Therefore, even if the active region is scraped in the region R₄₋₂, the upper and lower limits in the first product characteristic (Y₁) of the combined active region do not change and are not updated, and the upper and lower limits in the second product characteristic (Y₂) of the combined active region are updated. The upper limit in the second product characteristic (Y₂) is the Y₂ coordinate (0.630450) obtained by adding the average value (0.030450) of the distances between the Y₂ coordinate (0.6173, 0.5790, 0.5239, 0.6074) of the characteristic points B, D, F, and H and the standard center (0.6000) from the standard center. The lower limit in the second product characteristic (Y₂) is the Y₂ coordinate (0.569550) obtained by subtracting the average value (0.030450) of the distances between the Y₂ coordinate (0.6173, 0.5790, 0.5239, 0.6074) of the characteristic points B, D, F, and H and the standard center (0.6000) from the standard center.

The characteristic point having the twenty-seventh control number corresponds to characteristic point H in FIG. 40B, and is located below the standard center in the first product characteristic (Y₁) and above the standard center in the second product characteristic (Y₂).

Therefore, the optimization method (optimization purpose) in the first product characteristic (Y₁) and the second product characteristic (Y₂) is set to maximization and minimization. The optimization target value in the first product characteristic (Y₁) is set to the coordinates (1.417975) of the upper limit of the first product characteristic (Y₁) in the combined active region. The optimization target value in the second product characteristic (Y₂) is set to the coordinates (0.569550) of the lower limit of the second product characteristic (Y₂) in the combined active region.

Evaluation value calculating unit 12 calculates a predicted distribution of the twenty-eighth characteristic point for each candidate control point using the update equation of the Kalman filter such as (Equation 5) on the basis of the control results up to the control result of the twenty-seventh control number. Evaluation value calculating unit 12 calculates an acquisition function for each candidate control point using the calculated predicted distribution and an update equation of Bayesian optimization such as (Equation 7). The candidate control point having the maximum evaluation value obtained from the calculated acquisition function is adopted as the twenty-eighth control point.

By performing the above processing every time one set of control results is added, the control method 3 is performed in which the optimization target value is gradually moved from the standard upper and lower limits, which are initial values, to the standard center. As a result, it is possible to perform highly accurate and highly efficient control that does not depend on a person in the control of the time-series data.

Although evaluation device 100 according to an aspect of the present disclosure has been described above based on the above-described exemplary embodiment and each modification, the present disclosure is not limited to the exemplary embodiment and each modification. Various modifications conceivable by those skilled in the art may be applied to the exemplary embodiment or each modification described above without departing from the scope of the present disclosure.

Note that, in the above-described exemplary embodiments and the like, each component may be configured by dedicated hardware or may be implemented by executing a software program suitable for each component. Each component may be implemented by a program execution unit such as a CPU or a processor reading and executing a software program recorded in a recording medium such as a hard disk or a semiconductor memory. Here, the software that implements the evaluation device and the like of the above-described exemplary embodiment and the like is, for example, a program that causes a computer to execute each step of the flowchart illustrated in FIG. 10.

Note that the following cases are also included in the present disclosure.

(1) The at least one device is specifically a computer system including a microprocessor, a read only memory (ROM), a random access memory (RAM), a hard disk unit, a display unit, a keyboard, a mouse, and the like. The RAM or the hard disk unit stores a computer program. The microprocessor operates in accordance with the computer program, whereby the at least one device achieves its functions. Here, the computer program is configured by combining a plurality of instruction codes indicating commands to the computer in order to achieve a predetermined function.

(2) A part or all of the components constituting the at least one device may be constituted by one system large scale integration (LSI). The system LSI is a super multifunctional LSI manufactured by integrating a plurality of components on one chip, and is specifically a computer system including a microprocessor, a ROM, a RAM, and the like. The RAM stores a computer program. By the microprocessor operating in accordance with the computer program, the system LSI achieves its functions.

(3) A part or all of the components constituting the at least one device may be constituted by an IC card detachable from the device or a single module. The IC card or the module is a computer system including a microprocessor, a ROM, a RAM, and the like. The IC card or the module may include the above-described super multifunctional LSI. The microprocessor operates in accordance with the computer program, whereby the IC card or the module achieves its function. The IC card or the module may have tamper resistance.

(4) The present disclosure may be the methods described above. In addition, the present disclosure may be a computer program causing a computer to implement these methods, or may be a digital signal including a computer program.

Furthermore, the present disclosure may be a computer program or a digital signal recorded in a computer-readable recording medium such as a flexible disk, a hard disk, a compact disc (CD)-ROM, a DVD, a DVD-ROM, a DVD-RAM, a Blu-ray (registered trademark) disc (BD), or a semiconductor memory. In addition, it may be a digital signal recorded in these recording media.

Furthermore, the present disclosure may be a computer program or a digital signal transmitted via an electric communication line, a wireless or wired communication line, a network represented by the Internet, data broadcasting, or the like.

In addition, the program or the digital signal may be recorded on a recording medium and transferred, or the program or the digital signal may be transferred via a network or the like to be implemented by another independent computer system.

According to the evaluation device of the present disclosure, it is possible to quantitatively evaluate a candidate control point capable of suppressing an overshoot phenomenon or a hunting phenomenon with respect to a control problem of time-series data.

### INDUSTRIAL APPLICABILITY

The evaluation device of the present disclosure has an effect of being able to quantitatively and efficiently search for an optimal process condition even when there is a constraint condition by a standard range in product characteristics, and can be applied not only to mass production sites of industrial products but also to applications of optimal control such as space simulation and trajectory control of dynamic objects.

### REFERENCE MARKS IN THE DRAWINGS

10: reception controller
11: candidate control point creating unit
12: evaluation value calculating unit
13: evaluation value output unit
100: evaluation device
101a: input unit
101b: communication unit
102: arithmetic circuit
103: memory
104: display unit
105: storage unit
200: program
201: characteristic point data
210: setting information
211: process condition data
212: purpose data
213: constraint condition data
214: region reduction rule data
221: candidate control point data
222: control result data
223: predicted distribution data
224: evaluation value data
300: reception image
310: process condition region
311 to 314, 321 to 328: input field
320: product characteristic region
330: region reduction rule region

1. An evaluation device that evaluates, by Bayesian optimization, a plurality of unknown characteristic points corresponding to a plurality of candidate control points at a second time following a first time based on a known characteristic point corresponding to a controlled control point at the first time, the evaluation device comprising:
a first reception means that acquires control result data indicating the controlled control point at the first time and the known characteristic point at the first time;
a second reception means that acquires purpose data indicating an optimization purpose, each of the plurality of unknown characteristic points indicating values of one or a plurality of product characteristics, and at least one product characteristic among the one or the plurality of product characteristics having the optimization purpose;
a third reception means that acquires constraint condition data indicating a constraint condition applied to the at least one product characteristic;
a fourth reception means that acquires region reduction rule data indicating a division method of a characteristic space represented by the at least one product characteristic and indicating a dimension for reducing an active region for each region of the characteristic space divided by the division method;
a calculation means that calculates an evaluation value of each of the plurality of unknown characteristic points based on the control result data, the purpose data, the constraint condition data, and the region reduction rule data; and
an output means that outputs the evaluation value,
wherein the calculation means applies weighting according to a degree of conformity of the constraint condition to the evaluation value for the at least one product characteristic.

2. The evaluation device according to claim 1, wherein
the constraint condition is at least one constraint range,
the optimization purpose includes a first purpose of keeping product characteristics within any one of the at least one constraint range and a second purpose of minimizing or maximizing the product characteristics, and
the calculation means calculates, for each of the at least one product characteristic, the evaluation value by performing different weighting processing among
(i) a case where an interval of the product characteristic used to calculate the evaluation value is outside each of the at least one constraint range;
(ii) a case where the interval is within any one of the at least one constraint range, and the optimization purpose is the first purpose; and
(iii) a case where the interval is within any one of the at least one constraint range, and the optimization purpose is the second purpose.

3. The evaluation device according to claim 2, further comprising a candidate control point creating means that creates the plurality of candidate control points by combining values that satisfy predetermined conditions of a plurality of process conditions.

4. The evaluation device according to claim 2, wherein the calculation means calculates the evaluation value based on a constraint range having a shape different from a rectangle among the at least one constraint range.

5. The evaluation device according to claim 1, wherein the calculation means calculates a predicted distribution at the plurality of candidate control points using a Kalman filter, and calculates the evaluation value using the calculated predicted distribution.

6. The evaluation device according to claim 1, wherein the calculation means calculates the evaluation value using a Monte Carlo method.

7. An evaluation method for evaluating, by an evaluation device, a plurality of unknown characteristic points corresponding to a plurality of candidate control points at a second time following a first time by Bayesian optimization based on known characteristic points corresponding to controlled control points at the first time, the evaluation method comprising:
a first reception step of acquiring control result data indicating the controlled control point at the first time and the known characteristic point at the first time;
a second reception step of acquiring purpose data indicating an optimization purpose, each of the plurality of unknown characteristic points indicating values of one or a plurality of product characteristics, and at least one product characteristic among the one or the plurality of product characteristics having the optimization purpose;
a third reception step of acquiring constraint condition data indicating a constraint condition applied to the at least one product characteristic;
a fourth reception step of acquiring region reduction rule data indicating a division method of a characteristic space represented by the at least one product characteristic and indicating a dimension for reducing an active region for each region of the characteristic space divided by the division method;
a calculation step of calculating an evaluation value of each of the plurality of unknown characteristic points based on the control result data, the purpose data, the constraint condition data, and the region reduction rule data; and
an output step of outputting the evaluation value,
wherein in the calculation step, weighting according to a degree of conformity of the constraint condition is applied to the evaluation value for the at least one product characteristic.

8. A program for causing a computer to evaluate, by Bayesian optimization based on a known characteristic point corresponding to a controlled control point at a first time, a plurality of unknown characteristic points corresponding to a plurality of candidate control points at a second time following the first time, the program causing the computer to execute:
a first reception step of acquiring control result data indicating the controlled control point at the first time and the known characteristic point at the first time;
a second reception step of acquiring purpose data indicating an optimization purpose, each of the plurality of unknown characteristic points indicating values of one or a plurality of product characteristics, and at least one product characteristic among the one or the plurality of product characteristics having the optimization purpose;
a third reception step of acquiring constraint condition data indicating a constraint condition applied to the at least one product characteristic;
a fourth reception step of acquiring region reduction rule data indicating a division method of a characteristic space represented by the at least one product characteristic and indicating a dimension for reducing an active region for each region of the characteristic space divided by the division method;
a calculation step of calculating an evaluation value of each of the plurality of unknown characteristic points based on the control result data, the purpose data, the constraint condition data, and the region reduction rule data; and
an output step of outputting the evaluation value,
wherein in the calculation step, weighting according to a degree of conformity of the constraint condition is applied to the evaluation value for the at least one product characteristic.
